(19) United States
(12) Patent Application Publication
(10) Pub. No.: US 2025/0089531 A1
(43) Pub. Date: Mar. 13, 2025

(54) DISPLAY DEVICE AND METHOD OF MANUFACTURING THE SAME

(71) Applicant: Samsung Display Co., LTD., Yongin-si (KR)

(72) Inventors: SANGDUK LEE, Yongin-si (KR); HOIKWAN LEE, Yongin-si (KR); EUN-KYUNG YEON, Yongin-si (KR); HYUNKYUNG YUN, Yongin-si (KR); JUNGKYU LEE, Yongin-si (KR)

(21) Appl. No.: 18/745,781

(22) Filed: Jun. 17, 2024

(30) Foreign Application Priority Data
Sep. 8, 2023 (KR) 10-2023-0119765

(51) Int. Cl. H10K 59/80; H10K 59/90; H10K 102/00

(52) U.S. Cl. CPC H10K 59/873; H10K 59/8792; H10K 59/90; H10K 2102/311

(57) ABSTRACT

A display device includes a display panel including a display area and a non-display area surrounding the display area, a flexible board disposed in the non-display area and bent to allow a first end thereof to be disposed on a front surface of the display panel and a second end thereof to be disposed on a rear surface of the display panel, an optical unit disposed on the display panel and overlapping the display area, a transparent film disposed on the optical unit and covering the display area, the non-display area, and a bent portion of the flexible board when viewed in a plan view, and a coating window disposed directly on the transparent film and including a cured resin material.

This application claims priority to Korean Patent Application No. 10-2023-0119765, filed on Sep. 8, 2023, and all the benefits accruing therefrom under 35 U.S.C. § 119, the content of which in its entirety is herein incorporated by reference.

### BACKGROUND

### 1. Field

The disclosure relates to a display device and a method of manufacturing the display device. More particularly, the disclosure relates to a display device including a coating window and a method of manufacturing the display device.

### 2. Description of the Related Art

Display devices for providing images to a user, such as televisions, monitors, smartphones, and tablet computers, include a display panel for displaying the images. Various display panels, such as a liquid crystal display panel, an organic light emitting display panel, an electrowetting display panel, and an electrophoretic display panel, are being developed. In addition, the display device typically includes a window to protect the display panel. The window may be attached to the display panel through a lamination process.

### SUMMARY

Embodiments of the disclosure provide a display device including a transparent film to manufacture a coating window.

Embodiments of the disclosure provide a method of manufacturing the display device including the transparent film to manufacture the coating window.

Embodiments of the invention provide a display device including a display panel including a display area and a non-display area surrounding the display area, a flexible board disposed in the non-display area and bent to allow a first end thereof to be disposed on a front surface of the display panel and a second end thereof to be disposed on a rear surface of the display panel, an optical unit disposed on the display panel and overlapping the display area, a transparent film disposed on the optical unit and covering the display area, the non-display area, and a bent portion of the flexible board when viewed in a plan view, and a coating window disposed directly on the transparent film and including a cured resin material.

In an embodiment, an outer side surface of the transparent film may protrude further in a direction away from the display area than a point of the bent portion, which is the most distant from the display area, of the flexible board when viewed in the plan view.

In an embodiment, the display device may further include a light blocking pattern disposed directly on a lower surface of the transparent film and covering the bent portion of the flexible board when viewed in the plan view.

In an embodiment, the display device may further include an adhesive layer disposed between the transparent film and the optical unit and attaching the transparent film to the optical unit, and the adhesive layer may have a thickness greater than a thickness of the light blocking pattern.

In an embodiment, the display device may further include a light blocking pattern disposed directly on an upper surface of the transparent film and covering the bent portion of the flexible board when viewed in the plan view.

In an embodiment, an outer side surface of the transparent film may be aligned with an outer side surface of the coating window when viewed in a cross-section.

In an embodiment, the transparent film may have a size equal to or greater than a size of the coating window when viewed in the plan view.

In an embodiment, an upper surface of the coating window may include a first portion which is flat and a second portion disposed outside of the first portion and having a thickness decreasing as a distance from a side surface thereof decreases.

In an embodiment, the transparent film may have a thickness equal to or greater than about 20 micrometers and equal to or smaller than about 200 micrometers.

In an embodiment, an outer side surface of the transparent film may protrude further in a direction away from the display area than an outer side surface of the display panel when viewed in a cross-section.

Embodiments of the invention provide a display device including a display panel including a non-bending area and a bending area extending from an end of the non-bending area and bent, an optical unit disposed on the display panel and overlapping the non-bending area, a transparent film disposed on the optical unit and overlapping the bending area and the non-bending area, and covering the bending area when viewed in a plan view, and a coating window disposed directly on the transparent film and including a cured resin material.

In an embodiment, the display device may further include a bending protective layer disposed on the display panel and bent together with the bending area, and the transparent film covers a bent portion of the bending protective layer.

In an embodiment, an outer side surface of the transparent film may protrude further in a direction away from the non-bending area than a point of the bending area, which is the most distant from the non-bending area, when viewed in the plan view.

In an embodiment, an outer side surface of the transparent film may protrude further in a direction away from the non-bending area than a point of the bent portion of the bending protective layer, which is the most distant from the non-bending area, when viewed in the plan view.

In an embodiment, the display device may further include a light blocking pattern disposed directly on a lower surface or an upper surface of the transparent film and covering the bending area when viewed in the plan view.

In an embodiment, the transparent film may have a size equal to or greater than a size of the coating window when viewed in the plan view.

Embodiments of the invention provide a method of manufacturing a display device including forming an upper structure including a transparent film, coupling the upper structure with a lower module including a display panel including a display area and a non-display area surrounding the display area and a bending member disposed on the display panel and bendable, forming a coating window directly on the transparent film using a curable resin material, and bending the bending member. In such embodiments, the transparent film covers the display area, the non-display area, and the bent portion of a bending member when viewed in a plan view.

In an embodiment, the forming the upper structure includes forming a light blocking pattern on an upper surface or a lower surface of the transparent film in a way such that the light blocking pattern covers the bent portion of the bending member when viewed in the plan view after the coupling the upper structure with the lower module.

In an embodiment, the forming the upper structure may include forming a light blocking pattern on an upper surface or a lower surface of the transparent film in a way such that the light blocking pattern covers the bent portion of the bending member when viewed in the plan view after the coupling the upper structure with the lower module, and forming an optical unit on the transparent film in a way such that the optical unit overlaps the display area after the coupling the upper structure with the lower module.

In an embodiment, the forming the upper structure may include forming a light blocking pattern on an upper surface or a lower surface of the transparent film in a way such that the light blocking pattern covers the bent portion of the bending member when viewed in the plan view after the coupling the upper structure with the lower module, and forming an optical unit on the transparent film in a way such that the optical unit overlaps the display area after the coupling the upper structure with the lower module, where the forming the coating window is performed before the coupling the upper structure with the lower module.

In an embodiment, the forming the coating window may include coating the curable resin material on the transparent film and curing the curable resin material coated on the transparent film.

In an embodiment, the bending member may be a flexible board which overlaps the non-display area and is bent to allow a first end thereof to be disposed on a front surface of the display panel and a second end thereof to be disposed on a rear surface of the display panel.

According to embodiments of the invention, the display device includes the transparent film that is disposed directly under the coating window and serves as a base layer when the resin material is coated to form the coating window.

According to embodiments of the invention, the light blocking pattern disposed on the transparent film extends to the outer side surface of the display panel and prevents the bent portion of the display panel and the bent portion of the circuit board from being viewed from the outside.

According to embodiments of the method of manufacturing the display device, the manufacturing process is simplified, and thus, the reliability and economic efficiency of the process is improved.

### BRIEF DESCRIPTION OF THE DRAWINGS

The above and other features of embodiments of the disclosure will become readily apparent by reference to the following detailed description when considered in conjunction with the accompanying drawings, in which:

FIG. 1 is a perspective view of a display device according to an embodiment of the disclosure;

FIGS. 2A and 2B are exploded perspective views of a display device according to an embodiment of the disclosure;

FIG. 3 is a plan view of a display panel according to an embodiment of the disclosure;

FIG. 4 is a plan view of a touch sensing panel according to an embodiment of the disclosure;

FIG. 5 is a cross-sectional view of a display device according to an embodiment of the disclosure;

FIG. 6 is a cross-sectional view of a display device according to an embodiment of the disclosure;

FIG. 7 is a cross-sectional view of a display device according to an embodiment of the disclosure;

FIG. 8 is a cross-sectional view of a display device according to an embodiment of the disclosure;

FIGS. 9A and 9B are exploded perspective views of a display device according to an embodiment of the disclosure;

FIG. 10 is a plan view of a display panel according to an embodiment of the disclosure;

FIG. 11 is a cross-sectional view of a display device according to an embodiment of the disclosure;

FIG. 12 is a cross-sectional view of a display device according to an embodiment of the disclosure;

FIGS. 13A to 13D are cross-sectional views of a method of manufacturing a display device according to an embodiment of the disclosure;

FIGS. 14A to 14C are cross-sectional views of a method of manufacturing a display device according to an embodiment of the disclosure;

FIGS. 15A to 15D are cross-sectional views of a method of manufacturing a display device according to an embodiment of the disclosure; and

FIGS. 16A to 16D are cross-sectional views of a method of manufacturing a display device according to an embodiment of the disclosure.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art.

In the disclosure, it will be understood that when an element (or area, layer, or portion) is referred to as being “on”, “connected to” or “coupled to” another element or layer, it can be directly on, connected or coupled to the other element or layer or intervening elements or layers may be present.

Like numerals refer to like elements throughout. In the drawings, the thickness, ratio, and dimension of components are exaggerated for effective description of the technical content.

It will be understood that, although the terms first, second, etc. may be used herein to describe various elements, these elements should not be limited by these terms. These terms are only used to distinguish one element from another element. Thus, a first element discussed below could be termed a second element without departing from the teachings of the disclosure.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items.

Spatially relative terms, such as “beneath”, “below”, “lower”, “above”, “upper” and the like, may be used herein for ease of description to describe one element or feature's relationship to another elements or features as shown in the figures.

It will be further understood that the terms “comprises” and/or “comprising,” or “include” and/or “including”, when used in this specification, specify the presence of stated features, integers, steps, operations, elements, and/or components, but do not preclude the presence or addition of one or more other features, integers, steps, operations, elements, components, and/or groups thereof.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms including technical and scientific terms used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments of the disclosure will be described with reference to the accompanying drawings.

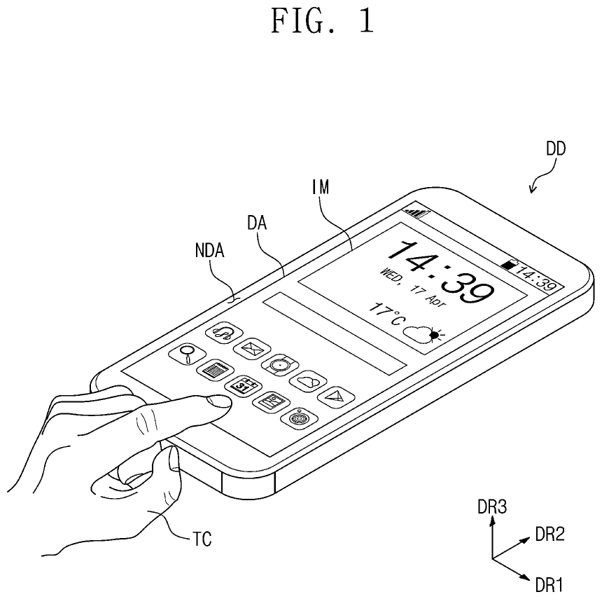

FIG. 1 is a perspective view of a display device DD according to an embodiment of the disclosure.

FIG. 1 shows an embodiment where the display device DD is a potable terminal as a representative example. The potable terminal may include a tablet computer, a smartphone, a personal digital assistant (PDA), a portable multimedia player (PMP), a game unit, a wrist-watch type electronic device, or the like. However, the disclosure should not be limited thereto or thereby.

An embodiment of the display device DD may be applied to a large-sized electronic device, such as a television set, an outdoor billboard, or the like, or a small and medium-sized electronic device, such as a personal computer (PC), a notebook computer, a car navigation unit, a camera, or the like. However, these are merely examples, and the display device DD may be employed in other electronic items as long as they do not depart from the invention of the disclosure.

In an embodiment, the display device DD of the disclosure may be flexible. The term “flexible” used herein refers to the property of being able to be bent from a structure that is completely bent to a structure that is bent at the scale of a few nanometers. For example, the flexible display device DD may be a curved display device, a foldable display device, a slidable display device, or a rollable display device. However, the disclosure should not be limited thereto or thereby, and the display device DD may be rigid.

In an embodiment, as shown in FIG. 1, a display surface on which an image IM is displayed may be substantially parallel to a plane defined by a first direction DR1 and a second direction DR2. The display device DD may include a plurality of areas distinguished from each other on the display surface. The display surface may include a display area DA on which the image IM is displayed and a non-display area NDA around the display area DA. The non-display area NDA may be referred to as a bezel area. in an embodiment, for example, the display area DA may have a quadrangular shape. The non-display area NDA may surround the display area DA. In an embodiment, although not shown in figures, the display device DD may have a curved shape in a portion thereof. In such an embodiment, the curved shape may be defined in a portion of the display area DA.

Front (or upper) and rear (or lower) surfaces of each member of the display device DD may be opposite to each other in a third direction DR3, and a normal line direction of each of the front and rear surfaces may be substantially parallel to the third direction DR3. A separation distance between the front and rear surfaces of each member (or each unit) in the third direction DR3 may correspond to a thickness in the member (or the unit) in the third direction DR3. Here, the third direction DR3 may be a thickness direction of the display device DD. In the disclosure, the expression “when viewed in a plan view” may mean a state of being viewed in the third direction DR3. In the disclosure, the expression “on a cross-section” may mean a state of being viewed in the first direction DR1 or the second direction DR2. Here, directions indicated by the first, second, and third directions DR1, DR2, and DR3 may be relative to each other, and thus, the directions indicated by the first, second, and third directions DR1, DR2, and DR3 may be changed to other directions. In the disclosure, the expression “one component overlaps another component” means that the two components overlap each other when viewed in the plan view or in the third direction DR3 unless otherwise specified.

In an embodiment, the front surface (or the upper surface or a first surface) and the rear surface (or the lower surface or a second surface) of each member of the display device DD may be defined with respect to a direction in which the image IM is displayed. Here, the directions indicated by the first, second, and third directions DR1, DR2, and DR3 may be relative to each other, and thus, the directions indicated by the first, second, and third directions DR1, DR2, and DR3 may be changed to other directions.

The display device DD may sense a touch input TC generated by a user and applied thereto from the outside. The touch input TC by the user may include a variety of external inputs, such as a touch event generated by a user's body part, light, heat, pressure, etc. In an embodiment, as shown in FIG. 1, the touch event generated by a user's hand will may be the touch input TC by the user, however, this is merely an example. As described above, the touch input TC by the user may be provided in various ways. In addition, the display device DD may sense the input by the user applied to a side or rear surface of the display device DD depending on its design, and it should not be particularly limited.

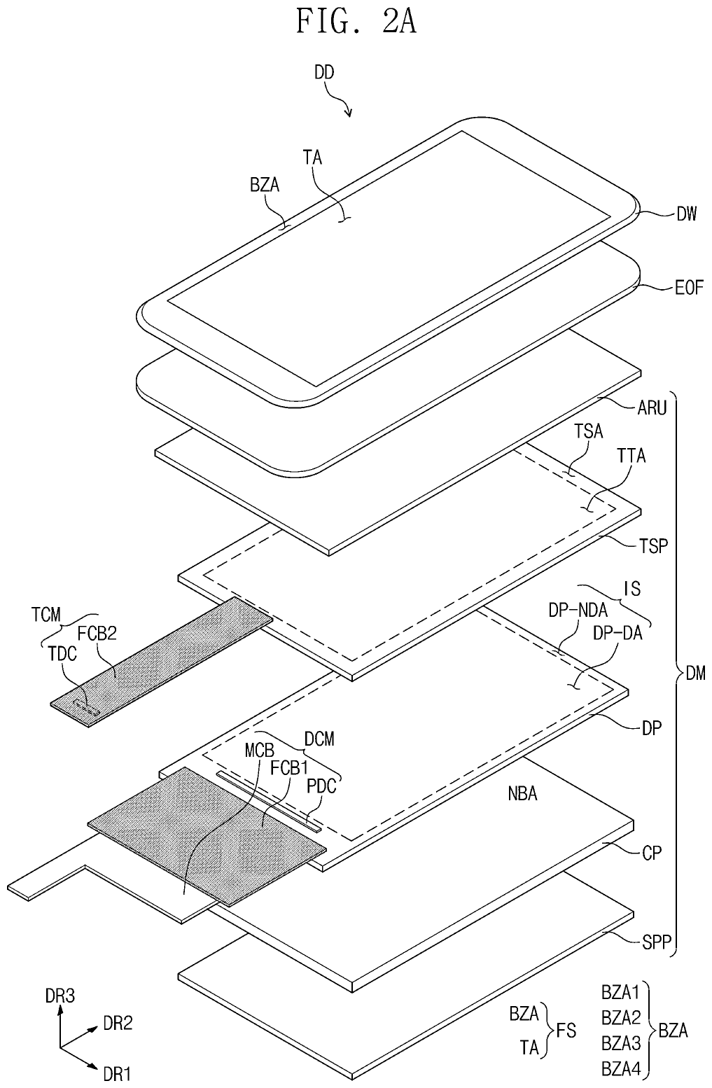

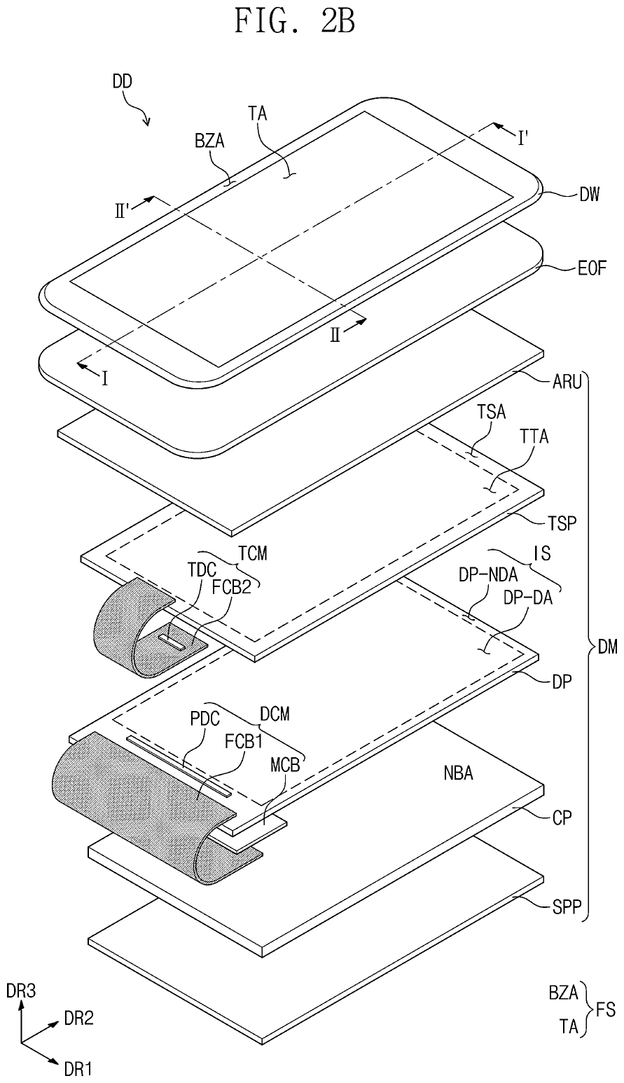

FIGS. 2A and 2B are exploded perspective views of the display device DD according to an embodiment of the disclosure. In detail, FIG. 2A is an exploded perspective view of the display device DD in a state in which a first circuit board (or a first flexible board) FCB1 and a second circuit board (or a second flexible board) FCB2 are not bent, and FIG. 2B is an exploded perspective view of the display device DD in a state in which the first circuit board FCB1 and the second circuit board FCB2 are bent.

Referring to FIGS. 2A and 2B, an embodiment of the display device DD may include a coating window DW, a transparent film EOF, and a display module DM. The coating window DW may be disposed directly on the transparent film EOF. The expression “the coating window DW is disposed directly on the transparent film EOF” Means that no intervening layer (for example, no separate adhesive or no adhesive layer) is disposed between the coating window DW and the transparent film EOF.

The coating window DW may provide a front surface FS of the display device DD. The front surface FS of the coating window DW may include a transmission area TA and a bezel area BZA. The transmission area TA of the coating window DW may be an optically transparent area. Accordingly, the coating window DW may transmit the image IM (refer to FIG. 1) provided from a display panel DP through the transmission area TA, and the user may view the image IM.

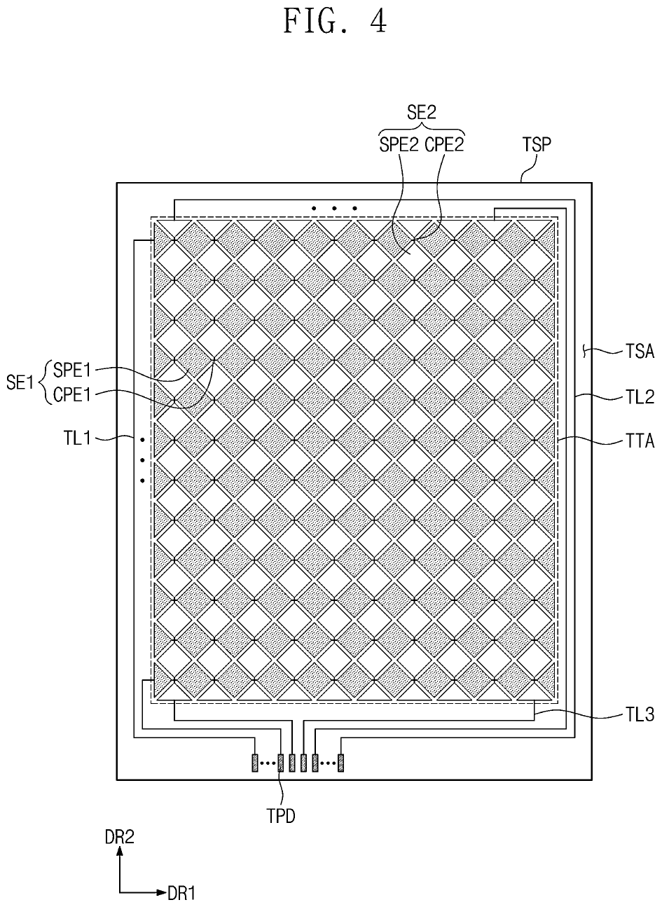

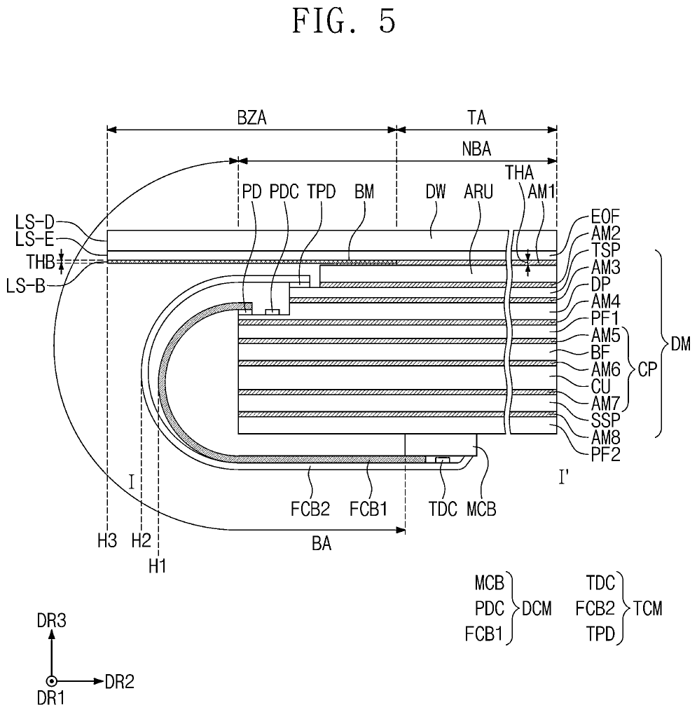

The bezel area BZA of the coating window DW may overlap a light blocking pattern BM (refer to FIG. 4) described later. The light blocking pattern BM may be a rigid substrate including a material having a predetermined color. The bezel area BZA of the coating window DW may prevent components of the display panel DP, which are disposed to overlap the light blocking pattern BM (refer to FIG. 5), from being viewed from the outside.

The bezel area BZA may be defined adjacent to the transmission area TA, and the shape of the transmission area TA may be defined by the bezel area BZA. In an embodiment, for example, the bezel area BZA may be disposed outside the transmission area TA and may surround the transmission area TA, however, it should not be limited thereto or thereby. In an embodiment, the bezel area BZA may be defined adjacent to only one side of the transmission area TA or may be omitted. In an embodiment, the bezel area BZA may be defined at a side surface of the display device DD rather than the front surface FS of the display device DD.

The coating window DW may include an optically transparent insulating material. In an embodiment, for example, the coating window DW may include a cured resin material, which is formed by curing a curable resin material. The coating window DW may have a single-layer or multi-layer structure. The coating window DW may be formed by coating a resin material on the transparent film EOF and curing the coated resin material. According to an embodiment of the display device DD including the coating window DW, a lamination process of attaching a window including or formed of a glass material to the display panel DP may be omitted in a method of manufacturing the display device DD. Accordingly, the manufacturing method of the display device DD may be simplified, and a manufacturing cost of the display device DD may be reduced.

The coating window DW may include functional layers, such as an anti-fingerprint layer, an anti-reflection layer or a hard coating layer, for example. In an embodiment, the coating window DW may have a flat shape in a display area DP-DA, however, the shape of the coating window DW may be changed. Edges of the coating window DW, which face each other in the first direction DR1, may be provided with a rounded surface.

The transparent film EOF may be disposed between the coating window DW and the display module DM. The transparent film EOF may be an optically transparent film. The transparent film EOF may include materials that are colorless and transparent and have high optical properties. In an embodiment, for example, the transparent film EOF may include polyimide (PI), polyethylene terephthalate (PET), or the like. However, materials for the transparent film EOF should not be limited thereto or thereby, and the transparent film EOF may include various materials as desired.

The transparent film EOF may be disposed on an optical unit ARU. The transparent film EOF may have a flat plate shape substantially parallel to a plane defined by the first direction DR1 and the second direction DR2. The transparent film EOF may cover the display area DP-DA and a non-display area DP-NDA when viewed in the plan view. The transparent film EOF may cover the transmission area TA and the bezel area BZA when viewed in the plan view. The transparent film EOF may cover a touch area TTA and a touch peripheral area TSA when viewed in the plan view. The transparent film EOF may have a size (or planar area) equal to or greater than a size of the coating window DW when viewed in the plan view.

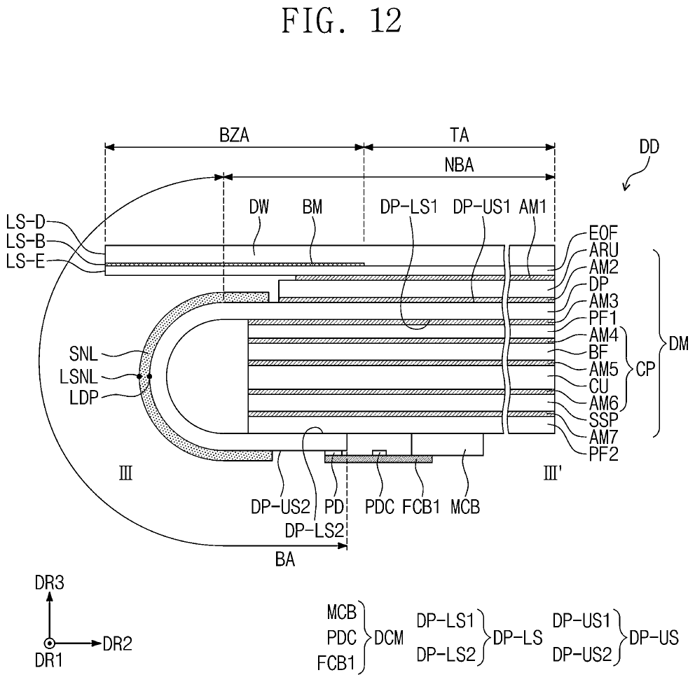

The transparent film EOF may act as a base layer on which a resin material used to form the coating window DW is coated. That is, the transparent film EOF having the flat plate shape may be disposed under the coating window DW, and the resin material that is in liquid state may be coated on the transparent film EOF. In addition, since the transparent film EOF covers the bent first and second flexible boards FCB1 and FCB2 when viewed in the plan view, the transparent film EOF may prevent the resin material from entering the flexible boards FCB1 and FCB2 and being cured when the resin material is coated. In a case where the resin material enters the flexible boards FCB1 and FCB2 and is cured, cracks may occur in the first and second flexible boards FCB1 and FCB2 when the first and second flexible boards FCB1 and FCB2 are bent through a bending process shown in FIG. 12D. The transparent film EOF may prevent the cracks from occurring.

The transparent film EOF may have a thickness equal to or greater than about 20 micrometers (μm) and equal to or smaller than about 200 μm. In a case where the thickness of the transparent film EOF is smaller than about 20 μm, the transparent film EOF may be deformed when the resin material is coated on the transparent film EOF. In a case where the thickness of the transparent film EOF is greater than about 200 μm, a thickness of the display device DD may significantly increase.

The display module DM may be disposed on a rear surface of the coating window DW and may generate the image IM (refer to FIG. 1). In addition, the display module DM may sense the touch input TC (refer to FIG. 1) by the user.

In FIGS. 2A and 2B, an embodiment in which the display module DM provides the flat display surface is shown as a representative example, however, the shape of the display module DM may be changed. In an embodiment, edges of the display module DM, which face each other in the first direction DR1, may be bent from center portions of sides and may be provided with the rounded surfaces.

The display module DM may include the optical unit ARU, a touch sensing panel TSP, a touch control unit TCM, the display panel DP, a protective panel CP, a support panel SPP, and a driving control module DCM.

The optical unit ARU may be disposed on the display panel DP and may overlap the display area DP-DA. The optical unit ARU may be disposed between the display panel DP and the transparent film EOF. The optical unit ARU may reduce a reflectance of a light incident thereto from the outside. The optical unit ARU may include at least one selected from a retarder, a polarizer, a polarization film, and a polarization filter. The optical unit ARU may be attached to the display panel DP by an adhesive layer. However, the types of the optical unit ARU should not be limited thereto or thereby. In an embodiment, for example, the optical unit ARU may include a color filter.

The display panel DP may be disposed between the coating window DW and the support panel SPP. The display panel DP may display the image IM in response to electrical signals. According to an embodiment, the display panel DP may be a light-emitting type display panel, however, it should not be particularly limited. In an embodiment, the display panel DP may be an organic light emitting display panel, an inorganic light emitting display panel, an organic-inorganic light emitting display panel, or a quantum dot light emitting display panel. A light emitting layer of the organic light emitting display panel may include an organic light emitting material. A light emitting layer of the inorganic light emitting display panel may include an inorganic light emitting material. A light emitting layer of the organic-inorganic light emitting display panel may include an organic-inorganic light emitting material. A light emitting layer of the quantum dot light emitting display panel may include a quantum dot or a quantum rod.

The image IM (refer to FIG. 1) provided by the display device DD may be displayed through a front surface IS of the display panel DP. The front surface IS of the display panel DP may include the display area DP-DA and the non-display area DP-NDA. The display area DP-DA may correspond to the display area DA of FIG. 1, and the non-display area DP-NDA may correspond to the non-display area NDA of FIG. 1.

The display area DP-DA may be activated in response to electrical signals, and the image may be displayed through the display area DP-DA. According to an embodiment, the display area DP-DA of the display panel DP may correspond to the transmission area TA of the coating window DW. In the following descriptions, the expression “an area/portion corresponds to another area/portion” means that “an area/portion overlaps another area/portion”, but they should not be limited to having the same area and/or the same shape.

The non-display area DP-NDA may be defined adjacent to an outer side of the display area DP-DA. In an embodiment, for example, the non-display area DP-NDA may surround the display area DP-DA, however, it should not be limited thereto or thereby. According to an embodiment, the non-display area DP-NDA may be defined or formed in a variety of shapes.

A driving circuit or a driving line to drive elements arranged in the display area DP-DA, various signal lines to provide electrical signals, and pads may be disposed in the non-display area DP-NDA. The non-display area DP-NDA of the display panel DP may correspond to the bezel area BZA of the coating window DW. Components of the display panel DP, which are disposed in the non-display area DP-NDA, may be effectively prevented from being viewed from the outside by the bezel area BZA.

The driving control module DCM may include a main circuit board MCB (or a driving circuit board), the first circuit board FCB1, and a panel driving circuit PDC. The first circuit board FCB1 may be connected to an end portion of the display panel DP to electrically connect the main circuit board MCB to the display panel DP.

The panel driving circuit PDC may be disposed in the non-display area DP-NDA of the display panel DP. The panel driving circuit PDC may be implemented in an integrated circuit. Although not shown in figures, a plurality of passive elements and a plurality of active elements may be mounted on the main circuit board MCB. The main circuit board MCB may be a rigid circuit board or a flexible circuit board, and the first circuit board FCB1 may be a flexible circuit board. The main circuit board MCB may be disposed on a rear surface of the display panel DP.

The first circuit board FCB1 may be disposed in the non-display area DP-NDA of the display panel DP and may be bent. The first circuit board FCB1 may be connected to the end of the display panel DP and may electrically connect the main circuit board MCB to the display panel DP. The first circuit board FCB1 may be bent in a way such that one end of the first circuit board FCB1 is disposed at the front surface of the display panel DP and another (or opposing) end of the first circuit board FCB1 is disposed at the rear surface of the display panel DP. The first circuit board FCB1 may be bent, and another (or opposing) end of the first circuit board FCB1 may be disposed at the rear surface of the display panel DP. The other end of the first circuit board FCB1 may be opposite to the rear surface of the display panel DP in the non-display area DP-NDA when viewed in the third direction DR3. The main circuit board MCB may be disposed on the rear surface of the display panel DP.

The touch sensing panel TSP may be disposed between the display panel DP and the optical unit ARU and may be connected to the second circuit board FCB2. The touch sensing panel TSP may obtain coordinate information of the touch input TC (refer to FIG. 1) generated by a user. The touch sensing panel TSP may sense a variety of inputs applied thereto from the outside of the display device DD. In an embodiment, for example, the touch sensing panel TSP may sense an input generated by a user's body, however, the disclosure should not be limited thereto or thereby. In an embodiment, for example, the touch sensing panel TSP may sense the external inputs provided in various forms, such as light, heat, or pressure. In addition, the touch sensing panel TSP may sense a contact input occurring on a sensing surface thereof and a proximity input applied when approaching close to the sensing surface.

The touch sensing panel TSP may be a capacitive type touch panel or an electromagnetic induction type touch panel. The touch sensing panel TSP may include a base layer, sensing electrodes, and signal lines connected to the sensing electrodes.

The touch control unit TCM may include the second circuit board FCB2 and a touch driving circuit TDC. The second circuit board FCB2 may electrically connect the main circuit board MCB to the touch sensing panel TSP, and the touch driving circuit TDC may be mounted on the second circuit board FCB2. Similar to the first circuit board FCB1, the second circuit board FCB2 may be bent. The touch driving circuit TDC may be implemented as an integrated circuit. The second circuit board FCB2 may be a flexible circuit board.

The protective panel CP may be disposed on the rear surface of the display panel DP and may protect the display panel DP from impacts. The protective panel CP may include a plastic film as a base layer thereof. The protective panel CP may include a single-layer or multi-layer structure.

The support panel SPP may be disposed on a rear surface of the protective panel CP and may support the display panel DP and the protective panel CP. The support panel SPP may be a metal plate with a rigidity higher than a predetermined level. The support panel SPP may be a stainless steel plate. The support panel SPP may have a black color to block an external light incident into the display panel DP.

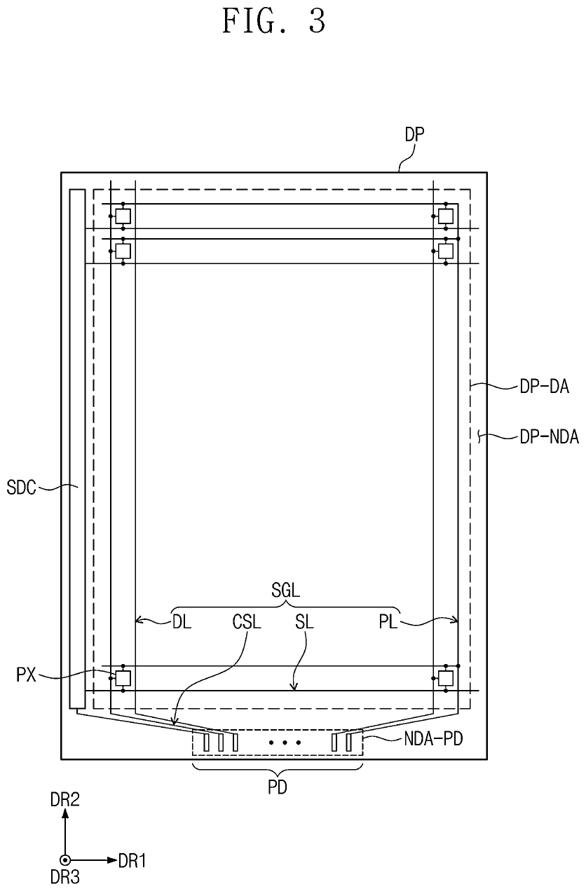

FIG. 3 is a plan view of the display panel DP according to an embodiment of the disclosure. FIG. 3 schematically shows a signal line diagram. In addition, for the convenience of illustration, some components of the display panel DP are omitted in FIG. 3.

Referring to FIG. 3, an embodiment of the display panel DP may include the display area DP-DA and the non-display area DP-NDA when viewed in the plane. In an embodiment, as shown in FIG. 3, the non-display area DP-NDA may be defined along an edge of the display area DP-DA. The display area DP-DA and the non-display area DP-NDA of the display panel DP may correspond to the display area DA and the non-display area NDA of the display device DD shown in FIG. 1, respectively.

The display panel DP may include a scan driving circuit SDC, a plurality of signal lines SGL, a plurality of signal pads PD, and a plurality of pixels PX. The pixels PX may be disposed in the display area DP-DA. Each of the pixels PX may include an organic light emitting diode and a pixel driving circuit connected to the organic light emitting diode.

The scan driving circuit SDC may generate a plurality of scan signals and may sequentially output the scan signals to a plurality of scan lines SL described later. The scan driving circuit SDC may further output a control signal to a driving circuit of the pixels PX.

The scan driving circuit SDC may include a plurality of thin film transistors formed through a same process as the driving circuit of the pixels PX, e.g., a low temperature polycrystalline silicon (LTPS) process or a low temperature polycrystalline oxide (LTPO) process.

The signal lines SGL may include the scan lines SL, data lines DL, a power line PL, and a control signal line CSL. Each of the scan lines SL may be connected to a corresponding pixel PX among the pixels PX, and each of the data lines DL may be connected to a corresponding pixel PX among the pixels PX. The power line PL may be connected to the pixels PX. The control signal line CSL may provide control signals to the scan driving circuit SDC.

The signal lines SGL may overlap the display area DP-DA and the non-display area DP-NDA. The signal lines SGL may include a pad part and a line part. The line part may overlap the display area DP-DA and the non-display area DP-NDA. The pad part may be connected to an end of the line part. The pad part may be disposed in the non-display area DP-NDA and may overlap a corresponding signal pad among the signal pads PD. In the non-display area DP-NDA, an area where the signal pads PD are arranged may be defined as a pad area NDA-PD.

The line part connected to the pixel PX may substantially form most of the signal lines SGL. The line part may be connected to transistors (not shown) of the pixel PX. The line part may have a single-layer or multi-layer structure, and the line part may be provided in the form of a single body or may be implemented by two or more portions. The two or more portions may be disposed in different layers from each other and may be connected to each other via a contact hole defined through an insulating layer disposed between the two or more portions.

FIG. 4 is a plan view of the touch sensing panel TSP according to an embodiment of the disclosure.

Referring to FIG. 4, an embodiment of the touch sensing panel TSP may sense the touch input TC (refer to FIG. 1) to obtain information about location and intensity of the external touch input. The touch sensing panel TSP may include the touch area TTA and the touch peripheral area TSA when viewed in the plan view. In an embodiment, the touch peripheral area TSA may be defined along an edge of the touch area TTA. The touch area TTA and the touch peripheral area TSA of the touch sensing panel TSP may correspond to the display area DA and the non-display area NDA of the display device DD shown in FIG. 1, respectively.

The touch sensing panel TSP may include a plurality of first sensing electrodes SE1, a plurality of second sensing electrodes SE2, a plurality of sensing lines TL1, TL2, and TL3, and a plurality of touch pads TPD.

The first sensing electrodes SE1 and the second sensing electrodes SE2 may be disposed in the touch area TTA. The touch sensing panel TSP may obtain the information about the touch input based on a variation in capacitance between the first sensing electrodes SE1 and the second sensing electrodes SE2.

The first sensing electrodes SE1 may extend in the first direction DR1 and may be arranged in the second direction DR2. The first sensing electrodes SE1 may include a plurality of first sensing patterns SPE1 and a plurality of first connection patterns CPE1.

The first sensing patterns SPE1 forming one first sensing electrode may be arranged spaced apart from each other in the first direction DR1. For the convenience of illustration, the first sensing patterns SPE1 are shown shaded in FIG. 4. The first connection patterns CPE1 may be disposed between the first sensing patterns SPE1 and may connect two first sensing patterns SPE1 adjacent to each other.

The second sensing electrodes SE2 may extend in the second direction DR2 and may be arranged in the first direction DR1. The second sensing electrodes SE2 may include a plurality of second sensing patterns SPE2 and a plurality of second connection patterns CPE2.

The second sensing patterns SPE2 forming one second sensing electrode may be arranged spaced apart from each other in the second direction DR2. The second connection patterns CPE2 may be disposed between the second sensing patterns SPE2 and may connect two second sensing patterns SPE2 adjacent to each other.

The sensing lines TL1, TL2, and TL3 may be disposed in the touch peripheral area TSA. The sensing lines TL1, TL2, and TL3 may include first sensing lines TL1, second sensing lines TL2, and third sensing lines TL3. The first sensing lines TL1 may be connected to the first sensing electrodes SE1, respectively. The second sensing lines TL2 may be connected to one ends of the second sensing electrodes SE2, respectively.

The third sensing lines TL3 may be connected to other ends (or opposing ends) of the second sensing electrodes SE2, respectively. The other ends of the second sensing electrodes SE2 may be opposite to the one ends of the second sensing electrodes SE2. According to an embodiment of the disclosure, the second sensing electrodes SE2 may be connected to the second sensing lines TL2 and the third sensing lines TL3. Accordingly, the second sensing electrodes SE2 having a relatively longer length than that of the first sensing electrodes SE1 may have uniform sensitivity over the entire area thereof. However, this is merely an example, and the third sensing lines TL3 may be omitted, and the disclosure should not be particularly limited.

The touch pads TPD may be disposed in the touch peripheral area TSA. The touch pads TPD may be connected to the sensing lines TL1, TL2, and TL3, respectively, and thus may be electrically connected to each of the first sensing electrodes SE1 and the second sensing electrodes SE2. The touch pads TPD may be connected to the second circuit board FCB2 (refer to FIG. 2B).

FIG. 5 is a cross-sectional view of the display device according to an embodiment of the disclosure. In detail, FIG. 5 is a cross-sectional view taken along line I-I′ of FIG. 2B.

In FIG. 5, an embodiment of the display panel DP having a single-layer structure is shown, however, an embodiment of the display panel DP may have a multi-layer structure. In an embodiment, the display panel DP may include a base layer, a circuit layer, a light emitting element layer, and an encapsulation layer. In addition, those skilled in the art would understand that other components know in the art may be further included in the display panel DP.

The stack structure of an embodiment of the display device DD is shown in FIG. 5A. In such an embodiment, the display device DD may include the display module DM, the transparent film EOF disposed on the display module DM, and the coating window DW disposed directly on the transparent film EOF. The display device DD may include the display panel DP, the optical unit ARU, the transparent film EOF, a first protective layer PF1, a second protective layer PF2, the protective panel CP, the support panel SPP, the touch sensing panel TSP, the coating window DW, and first, second, third, fourth, fifth, sixth, seventh, and eighth adhesive layers AM1, AM2, AM3, AM4, AM5, AM6, AM7, and AM8. The display device DD may include a non-bending area NBA and a bending area BA in which the first and second circuit boards FCB1 and FCB2 are bent.

Each of the first adhesive layer AM1 to the eighth adhesive layer AM8 described hereinafter may be a pressure sensitive adhesive (PSA) film, an optically clear adhesive (OCA) film, or an optically clear resin (OCR). The first to eighth adhesive layers AM1 to AM8 may include a light-curable (or light-cured) adhesive material or a heat-curable (or heat-cured) adhesive material, however, materials for the first to eighth adhesive layers AM1 to AM8 should not be particularly limited. In another embodiment, some of the first to eighth adhesive layers AM1 to AM8 may be omitted.

The display panel DP may be disposed between the touch sensing panel TSP and the protective panel CP. The display panel DP may display the image in response to the electrical signals.

The driving control module DCM may be coupled with an end portion of the display panel DP. The driving control module DCM may include the first circuit board FCB1, the panel driving circuit PDC, and the main circuit board MCB. The first circuit board FCB1 may electrically connect the main circuit board MCB to the display panel DP. The panel driving circuit PDC may be disposed on the display panel DP.

The first circuit board FCB1 may be electrically connected to the signal pads PD. The signal pads PD may correspond to the signal pads PD (refer to FIG. 3) disposed in the pad area NDA-PD of FIG. 3. The first circuit board FCB1 may be bent. The one end (or a first end) of the first circuit board FCB1 may be disposed on a front surface of the display panel DP, and the other end (or a second end opposite to the first end) of the first circuit board FCB1 may be disposed at the rear surface of the display panel DP. The other end of the first circuit board FCB1 may be connected to the main circuit board MCB.

The touch sensing panel TSP may be disposed on the display panel DP and may sense an input signal. The third adhesive layer AM3 disposed between the touch sensing panel TSP and the display panel DP may be omitted. The touch sensing panel TSP may be disposed between the display panel DP and the optical unit ARU and may be electrically connected to the second circuit board FCB2.

The touch control unit TCM may include the touch driving circuit TDC, the second circuit board FCB2, and the touch pad TPD. The touch control unit TCM may be coupled with an end portion of the touch sensing panel TSP. The touch pad TPD may be disposed on the touch sensing panel TSP. In such an embodiment, the touch pad TPD may be the same as the touch pad TPD shown in FIG. 4.

The second circuit board FCB2 may be connected to the end portion oof the touch sensing panel TSP and may electrically connect the main circuit board MCB to the touch sensing panel TSP. The second circuit board FCB2 may transmit the input signal sensed by the touch sensing panel TSP. The second circuit board FCB2 may be bent together with the first circuit board FCB1. One end (or a first end) of the second circuit board FCB2 may be disposed on a front surface of the touch sensing panel TSP, and the other end (or a second end opposite to the first send) of the second circuit board FCB2 may be disposed at a rear surface of the touch sensing panel TSP. The other end of the second circuit board FCB2 may be connected to the main circuit board MCB.

The optical unit ARU may be disposed on the upper surface of the display panel DP. The optical unit ARU may be disposed on the touch sensing panel TSP. The optical unit ARU may be disposed between the display panel DP and the coating window DW and may overlap the non-bending area NBA. According to the embodiment, the optical unit ARU may not overlap the bending area BA. The optical unit ARU may be attached to the touch sensing panel TSP by the second adhesive layer AM2, however, the second adhesive layer AM2 may be omitted selectively.

The transparent film EOF may be disposed on the optical unit ARU. The transparent film EOF may extend to overlap the transmission area TA and the bezel area BZA. The transparent film EOF may cover the display module DM disposed under the transparent film EOF. The transparent film EOF may cover the bent portion of the first circuit board FCB1 when viewed in the plan view. The transparent film EOF may cover the bent portion of the second circuit board FCB2 when viewed in the plan view.

An outer side surface LS-E of the transparent film EOF may protrude further in a direction away from the display area DP-DA (or be more distant from the display area DP-DA in the second direction DR2) (refer to FIG. 2B) than a point H1 in the bent portion of the first circuit board FCB1 that is the most distant from the transmission area TA corresponding to the display area DP-DA (refer to FIG. 2B) when viewed in the plan view. That is, the outer side surface LS-E of the transparent film EOF may protrude further outward than the point H1 in the bent portion of the first circuit board FCB1, which is the most distant from the transmission area TA corresponding to the display area DP-DA (refer to FIG. 2B). In this case, the point H1 in the bent portion of the first circuit board FCB1, which is the most distant from the transmission area TA, may be the furthest point from the transmission area TA in the second direction DR2. The outer side surface LS-E of the transparent film EOF may protrude further in the direction away from the display area DP-DA (refer to FIG. 2B) than a point H2 in the bent portion of the second circuit board FCB2 that is the most distant from the transmission area TA corresponding to the display area DP-DA (refer to FIG. 2B) when viewed in the plan view. That is, a point H3 in a direction parallel to the second direction DR2 of the outer side surface LS-E of the transparent film EOF may protrude further outward than the point H1 of the first circuit board FCB1 that protrudes the most toward the outside in the direction parallel to the second direction DR2 and the point H2 of the second circuit board FCB2 that protrudes the most toward the outside in the direction parallel to the second direction DR2.

The light blocking pattern BM may be disposed directly on a lower surface of the transparent film EOF. The light blocking pattern BM may include a light blocking material and may effectively prevent components disposed thereunder from being viewed from an outside. In an embodiment, for example, the light blocking material may be a black colored resin that does not transmit the light. The light blocking pattern BM may be disposed to overlap the non-display area DP-NDA (refer to FIG. 2B) of the display panel DP. The light blocking pattern BM may be disposed to overlap the bezel area BZA of the coating window DW.

The light blocking pattern BM may cover the bent portion of the first circuit board FCB1 and the bent portion of the second circuit board FCB2 when viewed in the plan view. The light blocking pattern BM may be coupled with the display module DM after being printed on the lower surface of the transparent film EOF. Since the transparent film EOF extends outward more than the bent portions of the first and second circuit boards FCB1 and FCB2, the light blocking pattern BM printed on the transparent film EOF may also extend outward more than the bent portions of the first and second circuit boards FCB1 and FCB2. Accordingly, the first and second circuit boards FCB1 and FCB2 disposed under the light blocking pattern BM may not be viewed from the outside.

In an embodiment, the first adhesive layer AM1 may be disposed between the transparent film EOF and the optical unit ARU, and the transparent film EOF may be attached to the optical unit ARU by the first adhesive layer AM1. In such an embodiment, the first adhesive layer AM1 may have a thickness THA greater than a thickness THB of the light blocking pattern BM. When the transparent film EOF on which the light blocking pattern BM is printed is coupled with the display module DM, a surface in which a step difference is formed due to the thickness of the light blocking pattern BM may be coupled with the display module DM. The thickness THA of the first adhesive layer AM1 may be formed greater than the thickness THB of the light blocking pattern BM to prevent the transparent film EOF from being separated from the display module DM. Since the first adhesive layer AM1, like a PSA film, is deformed when applied with pressure, the transparent film EOF may be effectively prevented from being separated due to the light blocking pattern BM even though the first adhesive layer AM1 partially overlaps the light blocking pattern BM.

In a case where the coating window DW is formed by coating a resin material and curing the coated resin material, it is impossible to attach the light blocking pattern BM to the rear surface of the coating window DW. Accordingly, the optically transparent film EOF may be provided separately from the coating window DW, the light blocking pattern BM may be printed on the transparent film EOF, and thus, the light blocking pattern BM may cover the bending area BA.

The coating window DW may be disposed directly on the transparent film EOF. In an embodiment, the coating window DW may be formed by coating the resin material and curing the coated resin material. An outer side surface LS-D of the coating window DW may be aligned (or arranged in a straight line in the third direction DR3) with the outer side surface LS-E of the transparent film EOF when viewed in a cross-section. The outer side surface LS-E of the transparent film EOF may be aligned with an outer side surface LS-B of the light blocking pattern BM when viewed in the cross-section.

The first protective layer PF1 may be disposed on the rear surface of the display panel DP and may protect the display panel DP from external impacts. The first protective layer PF1 may be attached to the rear surface of the display panel DP by the fourth adhesive layer AM4. However, the fourth adhesive layer AM4 may be omitted selectively.

The second protective layer PF2 may be coupled with the driving control module DCM. The second protective layer PF2 may be disposed on the rear surface of the display panel DP. The second protective layer PF2 may be attached to the support panel SPP by the eighth adhesive layer AM8. However, the eighth adhesive layer AM8 may be omitted selectively.

The protective panel CP may be disposed on a lower surface DP-LS of the display panel DP. The protective panel CP may protect the display panel DP from impacts applied from a lower side thereof.

The protective panel CP may include the fifth adhesive layer AM5, a barrier layer BF, the sixth adhesive layer AM6, a cushion layer CU, and the seventh adhesive layer AM7. The barrier layer BF may be directly attached to a lower surface of the first protective layer PF1 by the fifth adhesive layer AM5. The barrier layer BF may have a color with low light transmittance and may effectively prevent components thereunder from being viewed.

The barrier layer BF may include a flexible synthetic resin film. In an embodiment, for example, the barrier layer BF may be a film including or containing polyimide (PI), polyethylene terephthalate (PET), or the like. However, it should not be limited thereto or thereby, and the barrier layer BF may include various materials.

The cushion layer CU may be attached to a lower surface of the barrier layer BF by the sixth adhesive layer AM6. The cushion layer CU may absorb impacts applied to the display panel DP from a lower side thereof. The cushion layer CU may include a highly elastic material such as a foam sheet in which a plurality of openings is defined or formed.

The support panel SPP may be disposed under the protective panel CP and may support the display panel DP and the protective panel CP. The support panel SPP may be a metal plate with a rigidity higher than a predetermined level. In an embodiment, for example, the support panel SPP may be a stainless steel plate. The support panel SPP may have a black color to block the external light incident into the display panel DP.

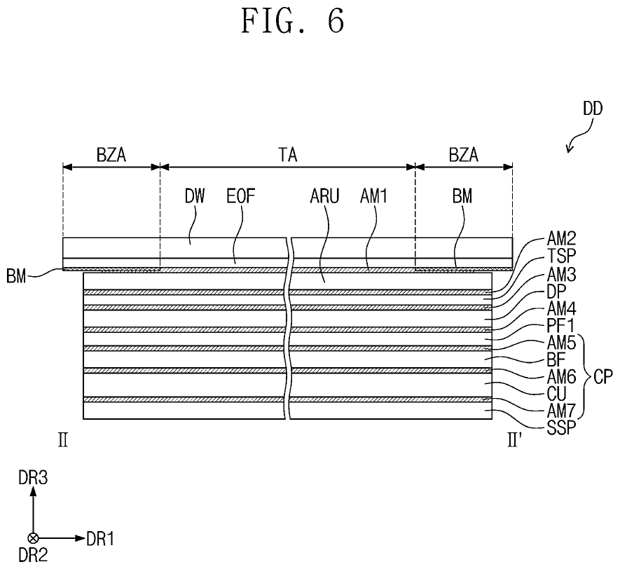

FIG. 6 is a cross-sectional view of the display device according to an embodiment of the disclosure. FIG. 6 is a cross-sectional view of the display device taken along line II-II′ of FIG. 2B.

Referring to FIG. 6, in an embodiment of the display device, the support panel SSP, the protective panel CP, the first protective layer PF1, the display panel DP, the touch sensing panel TSP, the optical unit ARU, the transparent film EOF, the light blocking pattern BM, and the coating window DW of the display device DD may be sequentially stacked.

The bezel area BZA may be disposed adjacent to both opposing sides of the transmission area TA. The bezel area BZA may correspond to the light blocking pattern BM. When viewed in a cross-section, an outermost side surface of the light blocking pattern BM and an outermost side surface of the transparent film EOF may protrude further outward than an outer side surface of the display panel DP, an outer side surface of the first protective layer PF1, an outer side surface of the protective panel CP, and an outer side surface of the support panel SSP. That is, the outermost side surface of the light blocking pattern BM and the outermost side surface of the transparent film EOF may protrude further than the outer side surface of the first protective layer PF1, the outer side surface of the protective panel CP, and the outer side surface of the support panel SSP in a direction parallel to the first direction DR1 to be away from the transmission area TA of the display area DP-DA (refer to FIG. 2B). The transparent film EOF may cover the display panel DP, the first protective layer PF1, the protective panel CP, and the support panel SSP when viewed in the plan view.

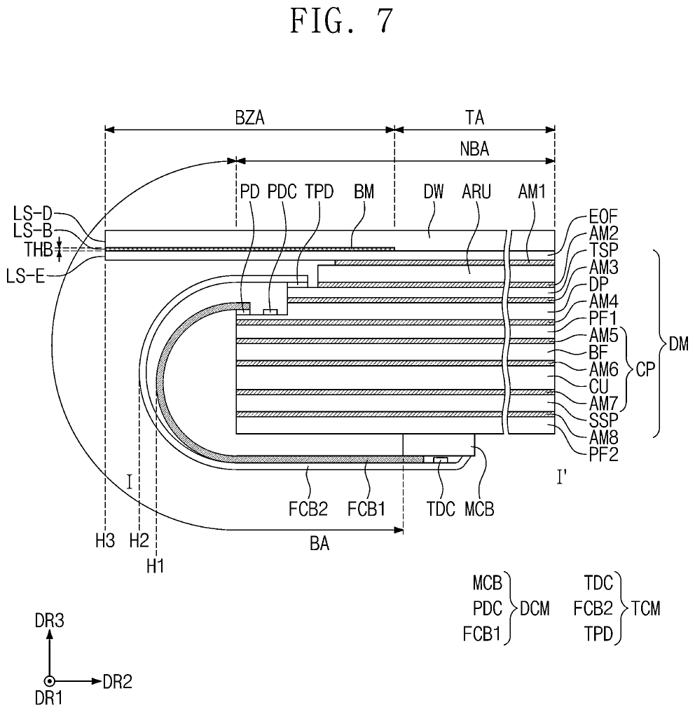

FIG. 7 is a cross-sectional view of a display device according to an embodiment of the disclosure. The display device of FIG. 7 is the same as the display device of FIG. 5 except a position of a light blocking pattern BM, the same reference numerals denote the same elements, and thus, any repetitive detailed descriptions of the same elements as those described above will be omitted.

Referring to FIG. 7, in an embodiment of a display device, the light blocking pattern BM may be disposed directly on an upper surface of a transparent film EOF and may cover bent portions of first and second circuit boards FCB1 and FCB2 when viewed in the plan view. The light blocking pattern BM may be substantially the same as the light blocking pattern BM shown in FIG. 5 except that the light blocking pattern BM of FIG. 7 is disposed on the upper surface of the transparent film EOF.

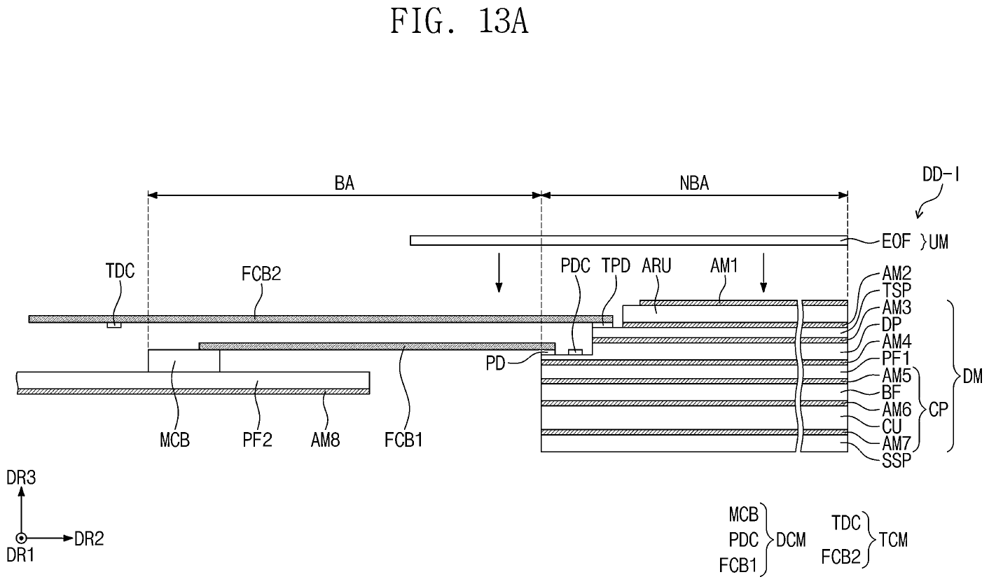

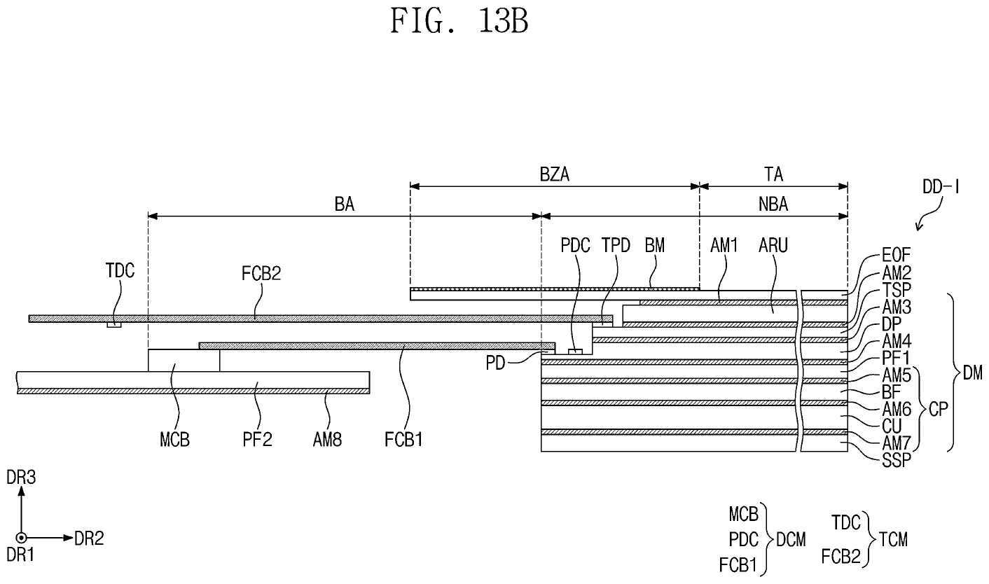

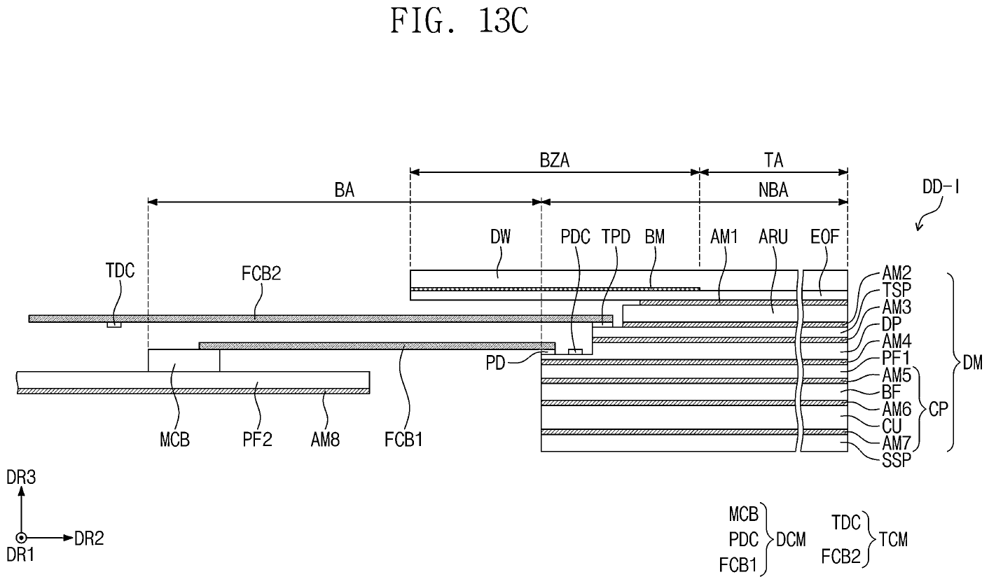

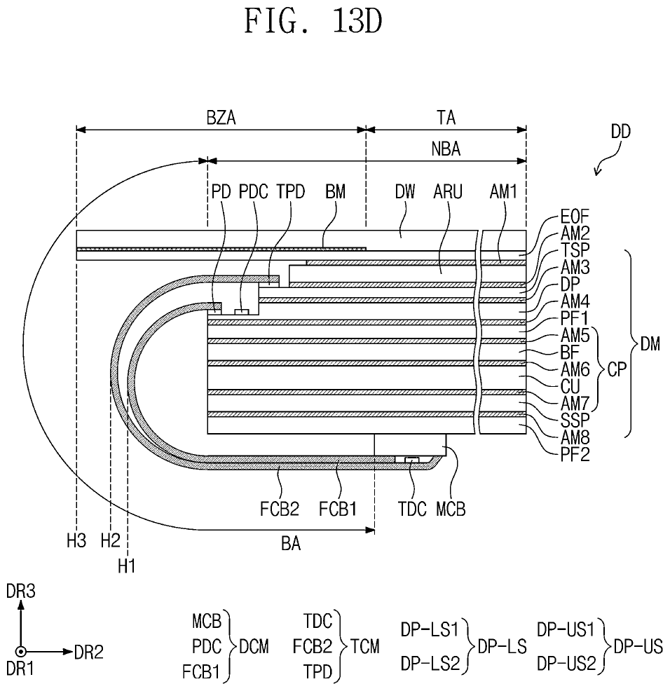

Since the light blocking pattern BM is disposed on the upper surface of the transparent film EOF, the light blocking pattern BM may be printed after the transparent film EOF is coupled with a display module DM. This will be described later with reference to FIGS. 13A and 13B.

In an embodiment, the coating window DW may be disposed directly on the transparent film EOF and the light blocking pattern BM. The coating window DW may be formed by coating a resin material and curing the coated resin material. A step difference corresponding to the light blocking pattern BM may be defined in a lower surface of the coating window DW. An upper surface of the coating window DW may be flat even though the step difference is formed in the lower surface of the coating window DW.

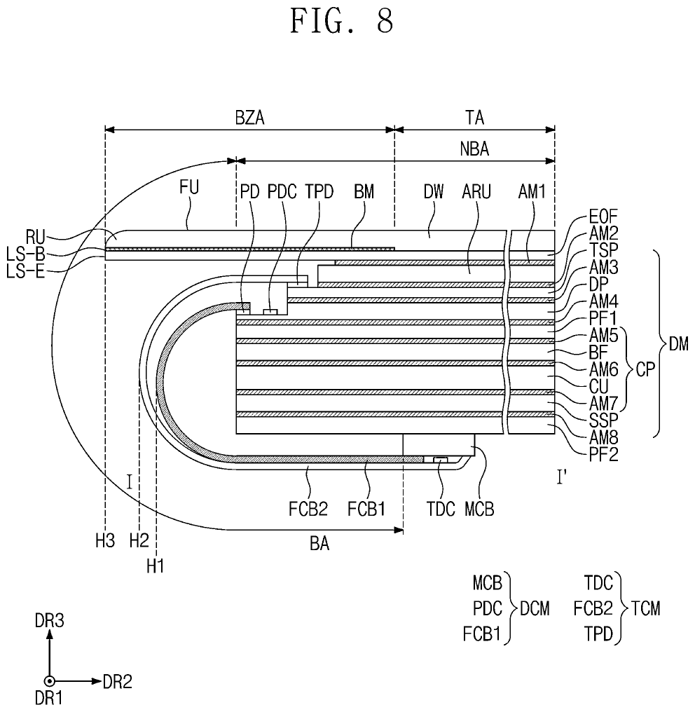

FIG. 8 is a cross-sectional view of a display device according to an embodiment of the disclosure. The display device of FIG. 8 is substantially the same as the display device described with reference to FIG. 7 except a shape of a coating window DW, and thus, any repetitive detailed description of the same elements as those described above will be omitted.

Referring to FIG. 8, in an embodiment of a display device, an upper surface of the coating window DW may include a first portion FU that is flat and a second portion RU that is curved. The first portion FU may overlap a transmission area TA. The second portion RU may overlap a bezel area BZA. The second portion RU may be disposed adjacent to an outer side of the first portion FU and may have a thickness decreasing as being toward to an outer side surface LS-E of a transparent film EOF or as a distance from the outer side surface LS-E of the transparent film EOF decreases. That is, the second portion RU may have a shape curved toward the transparent film EOF from the first portion FU when viewed in the cross-section.

When a resin material is coated to form the coating window DW, the first portion FU adjacent to a center of the display device DD (refer to FIG. 2B) may be coated evenly, and the second portion RU adjacent to an outer portion of the display device DD (refer to FIG. 2B) may be coated to have a curved shape. However, the shape of the upper surface of the coating window DW should not be limited thereto or thereby, and the upper surface of the coating window DW may have various shapes. In an embodiment, for example, like the coating window DW shown in FIGS. 5 and 7, the upper surface of the coating window DW may be flat by cutting the second portion RU. That is, an outer side surface LS-D (refer to FIGS. 5 and 7) of the coating window DW (refer to FIGS. 5 and 7) may be aligned with the outer side surface LS-E of the transparent film EOF when viewed in the cross-section by performing a separate cutting process.

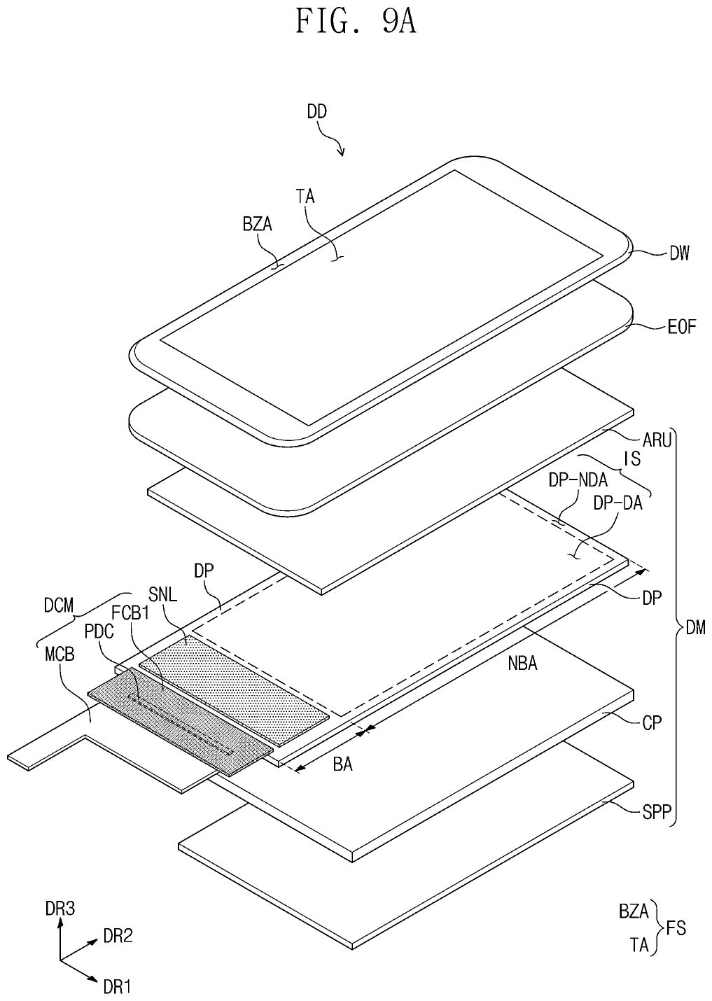

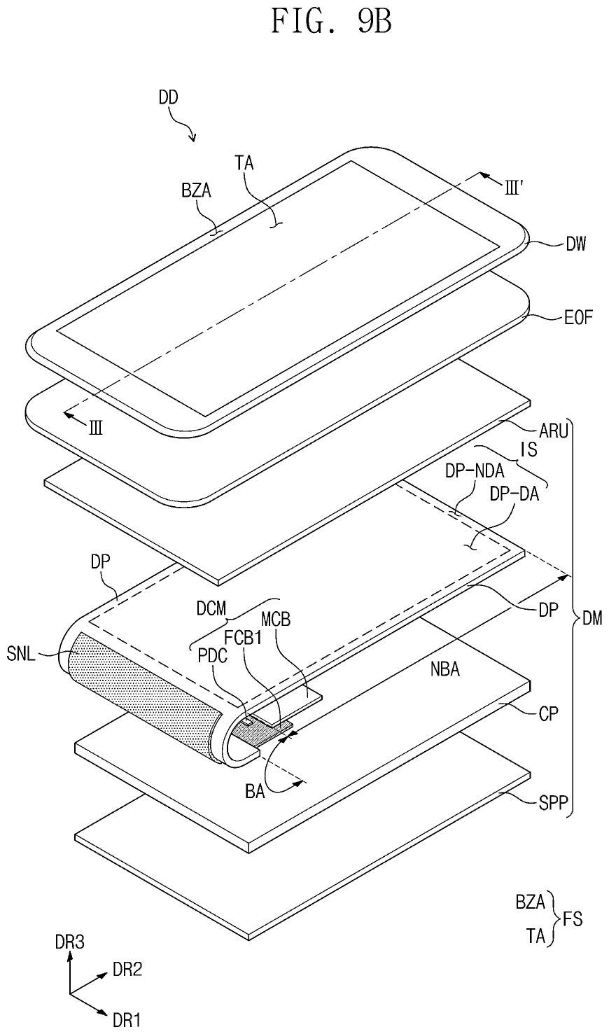

FIGS. 9A and 9B are exploded perspective views of a display device according to an embodiment of the disclosure. In detail, FIG. 9A is an exploded perspective view of the display device DD in which a bending area BA is not bent, and FIG. 9B is an exploded perspective view of the display device DD in which the bending area BA is bent. Hereinafter, in FIGS. 9A and 9B, the same reference numerals denote the same elements in FIGS. 2A and 2B, and thus, any repetitive detailed descriptions of the same elements as those described above will be omitted or briefly described.

Referring to FIGS. 9A and 9B, an embodiment of the display device DD may include a coating window DW, a transparent film EOF, and a display module DM. A display panel DP may be disposed between the coating window DW and a support panel SSP. The display panel DP may display an image in response to electrical signals.

The display panel DP may include a non-bending area NBA and the bending area BA extending from the non-bending area NBA and bent. The bending area BA may extend from the non-bending area NBA to a direction opposite to the second direction DR2. The bending area BA may be bent and then may be disposed to face a rear surface of the display panel DP in the non-bending area NBA.

The image IM (refer to FIG. 1) provided by the display device DD may be displayed through a front surface IS of the display panel DP. The front surface IS of the display panel DP may include a display area DP-DA and a non-display area DP-NDA. In an embodiment, the display area DP-DA may correspond to the display area DA of FIG. 1, and the non-display area DP-NDA may correspond to the non-display area NDA of FIG. 1.

A bending protective layer SNL may be disposed on the display panel DP and may be bent together with the bending area BA. The bending protective layer SNL may effectively prevent the bent portion of the display panel DP from being damaged due to external impacts or may effectively prevent a foreign substance from entering the bent portion of the display panel DP. The bending protective layer SNL shown in FIGS. 9A and 9B is merely an example, and a shape of the bending protective layer SNL may be changed as desired.

The bending protective layer SNL may be disposed on the front surface of the display panel DP and may protect the bent portion of the display panel DP. The bending protective layer SNL may include a plastic film as a base layer thereof. The bending protective layer SNL may include the plastic film that includes at least one selected from polyether sulfone (PES), polyacrylate (PAR), polyetherimide (PEI), polyethylene naphthalate (PEN), polyethylene terephthalate (PET), polyphenylene sulfide (PPS), polyarylate, polyimide (PI), polycarbonate (PC), poly(arylene ether sulfone), and combinations thereof.

However, a material for the bending protective layer SNL should not be limited to plastic resins, and the bending protective layer SNL may include organic/inorganic composite materials. The bending protective layer SNL may include a porous organic layer and an inorganic material filled in pores of the organic layer. The bending protective layer SNL may have a single-layer or multi-layer structure.

A driving control module DCM may include a main circuit board (or a driving circuit board) MCB, a first circuit board FCB1, and a panel driving circuit PDC. The first circuit board FCB1 may be connected to an end of the display panel DP and may electrically connect the main circuit board MCB and the display panel DP.

The first circuit board FCB1 may electrically connect the main circuit board MCB and the display panel DP, and the panel driving circuit PDC may be mounted on the first circuit board FCB1. The panel driving circuit PDC may be mounted on the first circuit board FCB1 by a chip-on-film (COF) method. The panel driving circuit PDC may be implemented as an integrated circuit. In another embodiment, although not shown in FIGS. 9A and 9B, a plurality of passive elements and a plurality of active elements may be mounted on the main circuit board MCB. The main circuit board MCB may be a rigid circuit board or a flexible circuit board, and the first circuit board FCB1 may be a flexible circuit board. The main circuit board MCB may be disposed on a rear surface of the display panel DP.

The transparent film EOF may cover the bent portion of the bending area BA and the bent portion of the bending protective layer SNL when viewed in the plan view. Since the transparent film EOF covers the bent portion of the bending area BA and the bent portion of the bending protective layer SNL, the transparent film EOF may effectively prevent a resin material from entering the bending area BA and the bending protective layer SNL and from being cured when the resin material is coated. In a case where the resin material enters the bending area BA and the bending protective layer SNL and is cured, cracks may occur in the display panel DP when the bending area BA and the bending protective layer SNL are bent. The transparent film EOF may effectively prevent cracks from occurring in the display panel DP.

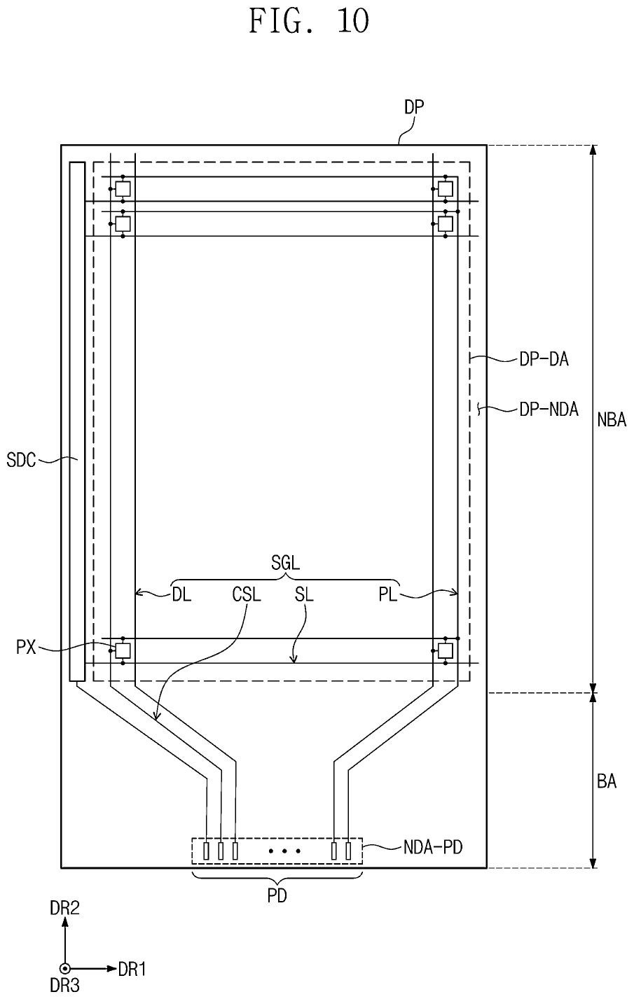

FIG. 10 is a plan view of the display panel DP according to an embodiment of the disclosure.

FIG. 10 schematically shows a signal line diagram. In FIG. 10, for the convenience of illustration and description, some components are omitted. Hereinafter, in FIG. 10, the same reference numerals denote the same elements in FIG. 3, and thus, any repetitive detailed descriptions of the same elements as those described above will be omitted.

Referring to FIG. 10, an embodiment of the display panel DP may include the non-bending area NBA and the bending area BA extending from the end of the non-bending area NBA and bent. In an embodiment, as shown in FIG. 10, the non-bending area NBA may be disposed at an upper side in the second direction DR2, and the bending area BA may be disposed at a lower side in the second direction DR2. A lower end of the bending area BA may be bent and may be disposed to face the non-bending area NBA.

The display panel DP may include a scan driving circuit SDC, a plurality of signal lines SGL, a plurality of signal pads PD, and a plurality of pixels PX. The pixels PX may be disposed in the display area DP-DA. Each of the pixels PX may include an organic light emitting diode and a pixel driving circuit connected to the organic light emitting diode.

The signal lines SGL may overlap the display area DP-DA, the non-display area DP-NDA, and the bending area BA. The signal lines SGL may include a pad part and a line part. The line part may overlap the display area DP-DA, the non-display area DP-NDA, and the bending area BA. The pad part may be connected to an end of the line part. The pad part may be disposed in the non-display area DP-NDA and may overlap a corresponding signal pad among the signal pads PD. In the non-display area DP-NDA, an area where the signal pads PD are arranged may be defined as a pad area NDA-PD.

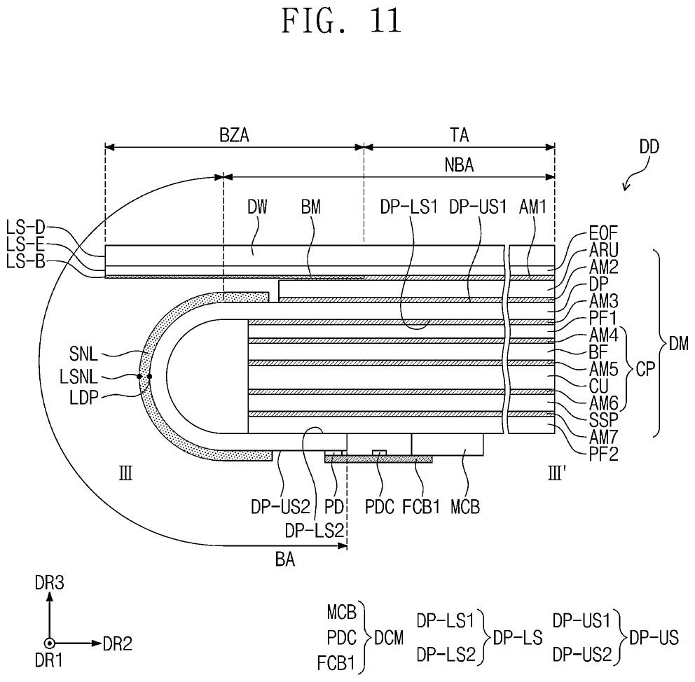

FIG. 11 is a cross-sectional view of the display device according to an embodiment of the disclosure. In FIG. 11, the same reference numerals denote the same elements in FIG. 5, and thus, any repetitive detailed descriptions of the same elements as those described above will be omitted.

Referring to FIG. 11, an embodiment of the display device DD may include the display module DM, the transparent film EOF, and the coating window DW disposed on the display module DM. The display module DM may include the display panel DP, an optical unit ARU, a first protective layer PF1, a second protective layer PF2, a protective panel CP, a support panel SSP, and first, second, third, fourth, fifth, sixth, and seventh adhesive layers AM1, AM2, AM3, AM4, AM5, AM6, and AM7. In an embodiment, some layers of the first adhesive layer AM1 to the seventh adhesive layer AM7 may be omitted.

The end of the bending area BA of the display panel DP may be bent and may be disposed on a lower surface of the second protective layer PF2. The end of the bending area BA may face the non-bending area NBA in the third direction DR3. A first upper surface DP-US1 of the display panel DP may be more adjacent to the coating window DW than a first lower surface DP-LS1 is. A second upper surface DP-US2 of the display panel DP may be spaced further away from the coating window DW than a second lower surface DP-LS2 is.

The optical unit ARU may be disposed on an upper surface DP-US of the display panel DP. The optical unit ARU may be disposed between the display panel DP and the coating window DW and may overlap the non-bending area NBA. According to an embodiment, the optical unit ARU may not overlap the bending area BA. The optical unit ARU may be attached to the display panel DP by the second adhesive layer AM2. However, the second adhesive layer AM2 may be omitted selectively.

The bending protective layer SNL may be disposed on the upper surface DP-US of the display panel DP and may be bent together with the bending area BA. The bending protective layer SNL may overlap the bending area BA. A portion of the bending protective layer SNL may partially overlap the non-bending area NBA of the display panel DP.

The driving control module DCM may be coupled with the end portion of the display panel DP. The driving control module DCM may include the first circuit board FCB1, the panel driving circuit PDC, and the main circuit board MCB. The first circuit board FCB1 may electrically connect the main circuit board MCB and the display panel DP, and the panel driving circuit PDC may be mounted on the first circuit board FCB1. In an embodiment, the panel driving circuit PDC is mounted on the first circuit board FCB1, however, a position of the panel driving circuit PDC should not be limited thereto or thereby. In an embodiment, for example, the panel driving circuit PDC may be disposed directly on the upper surface DP-US of the display panel DP.

The first circuit board FCB1 may be electrically connected to signal pads PD. The signal pads PD may correspond to the signal pads PD disposed in the pad area NDA-PD of FIG. 3.

The first protective layer PF1 may be disposed on the first lower surface DP-LS1 of the display panel DP and may protect the display panel DP from external impacts. The first protective layer PF1 may be attached to the first lower surface DP-LS1 by the third adhesive layer AM3. However, the third adhesive layer AM3 may be omitted selectively.

The transparent film EOF may be disposed on the optical unit ARU. The transparent film EOF may extend to overlap the bending area BA and the non-bending area NBA. The transparent film EOF may cover the display module DM disposed thereunder. The transparent film EOF may cover the bending area BA of the display panel DP and the bending protective layer SNL when viewed in the plan view.

An outer side surface LS-E of the transparent film EOF may protrude further in a direction away from the non-bending area NBA than a point LDP of the display panel DP in the bending area BA, which is the most distant from the non-bending area NBA when viewed in the plan view. The outer side surface LS-E of the transparent film EOF may protrude further in the direction away from the non-bending area NBA than a point LSNL of the bent portion of the bending protective layer SNL, which is the most distant from the non-bending area NBA when viewed in the plan view.

The light blocking pattern BM may be disposed directly on the lower surface of the transparent film EOF. The light blocking pattern BM may cover the bending area BA of the display panel DP and the bent portion of the bending protective layer SNL when viewed in the plan view. The light blocking pattern BM may be coupled with the display module DM after being printed on the lower surface of the transparent film EOF. The bending area BA and the bent portion of the bending protective layer SNL, which are disposed under the light blocking pattern BM, may not be viewed from the outside.

The first adhesive layer AM1 may be disposed between the transparent film EOF and the optical unit ARU, and the transparent film EOF may be attached to the optical unit ARU by the first adhesive layer AM1. In this case, the first adhesive layer AM1 may have a thickness greater than a thickness of the light blocking pattern BM.

The coating window DW may be disposed directly on the transparent film EOF. The coating window DW may be formed by coating a resin material and curing the coated resin material.

FIG. 12 is a cross-sectional view of a display device DD according to an embodiment of the disclosure. The display device DD shown in FIG. 12 is substantially the same as the display device DD shown in FIG. 11 except a position of a light blocking pattern BM. Accordingly, in FIG. 12, the same reference numerals denote the same elements in FIG. 11, and thus, any repetitive detailed descriptions of the same elements as those described above will be omitted.

Referring to FIG. 12, in an embodiment of a display device DD, the light blocking pattern BM may be disposed directly on an upper surface of a transparent film EOF and may cover a bending area BA and a bent portion of a bending protective layer SNL when viewed in the plan view. The light blocking pattern BM may be substantially the same as the light blocking pattern BM (refer to FIG. 11) shown in FIG. 11 except that the light blocking pattern BM of FIG. 12 is disposed on the upper surface of the transparent film EOF.

Since the light blocking pattern BM is disposed on the upper surface of the transparent film EOF, the light blocking pattern BM may be printed after the transparent film EOF is coupled with a display module DM.

The coating window DW may be disposed directly on the transparent film EOF and the light blocking pattern BM. The coating window DW may be formed by coating a resin material and curing the coated resin material. A step difference corresponding to the light blocking pattern BM may be formed in a lower surface of the coating window DW. An upper surface of the coating window DW may be flat even though the step difference is formed in the lower surface of the coating window DW.

FIGS. 13A to 13D are cross-sectional views of a method of manufacturing a display device according to an embodiment of the disclosure. In FIGS. 13A to 13D, the same reference numerals denote the same elements in the above-described embodiments, and thus, any repetitive detailed description of the same elements as those described above will be omitted.

Referring to FIG. 13A, in an embodiment of a method of manufacturing a display device, an upper structure UM including the transparent film EOF may be coupled with the display module (or a lower module) DM to form a preliminary display device DD-I. The transparent film EOF may be coupled with the optical unit ARU. The transparent film EOF may be attached to the optical unit ARU by the first adhesive layer AM1.

Referring to FIG. 13B, the light blocking pattern BM may be printed on the upper surface of the transparent film EOF. The light blocking pattern BM may protrude more outward than an outermost surface of the display panel DP. The light blocking pattern BM may correspond to the bezel area BZA.

Referring to FIG. 13C, the coating window DW may be formed on the upper surface of the transparent film EOF and the upper surface of the light blocking pattern BM. The coating window DW may be formed by coating the resin material on the transparent film EOF and curing the coated resin material. Since the transparent film EOF extends to the bending area BA, the coated resin material may not enter the first and second circuit boards FCB1 and FCB2 that are bent. Accordingly, the resin material may be prevented from entering the first and second circuit boards FCB1 and FCB2 and from being cured.

In a case where the coating window DW is formed as described above, costs may be reduced compared to using a conventional glass-type window. In addition, a separate lamination process and a process of forming an optically clear adhesive (OCA) may be omitted, and thus, a manufacturing process of the display device DD may be simplified and a reliability of manufacturing process may be improved.

Referring to FIG. 13D, the first and second circuit boards (or bending members) FCB1 and FCB2 may be bent to form the display device DD from the preliminary display device DD-I. As the first and second circuit boards FCB1 and FCB2 are bent, the second protective layer PF2 may be attached to the lower surface of the support panel SSP by the eighth adhesive layer AM8. In this case, the light blocking pattern BM may cover the bent portions of the first and second circuit boards FCB1 and FCB2 when viewed in the plan view.

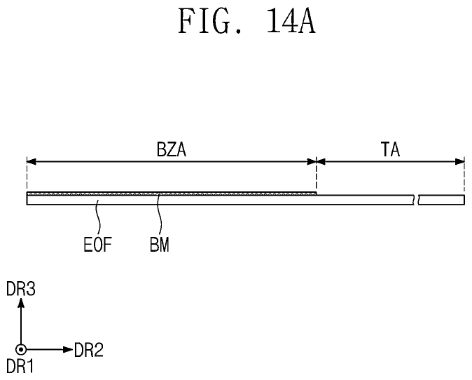

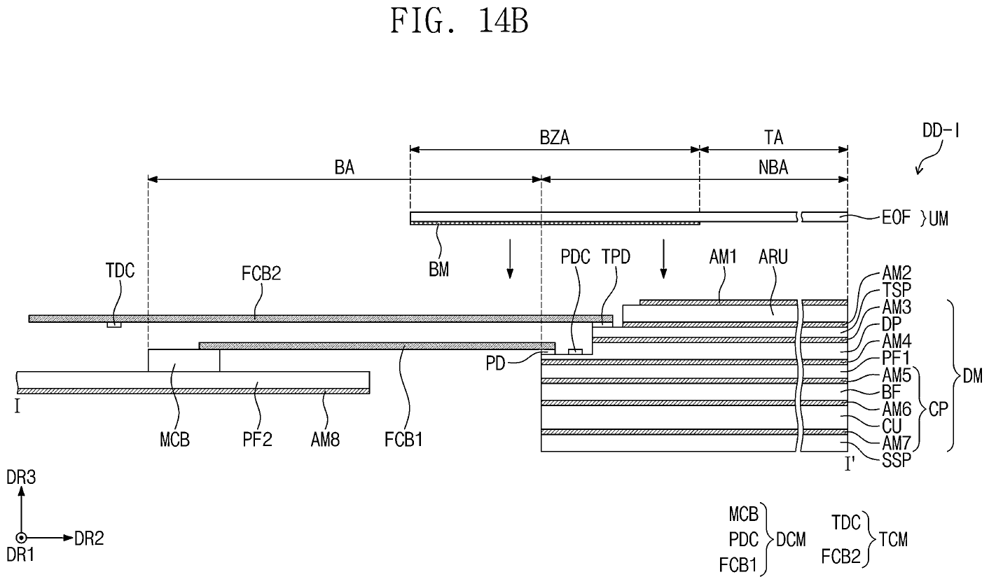

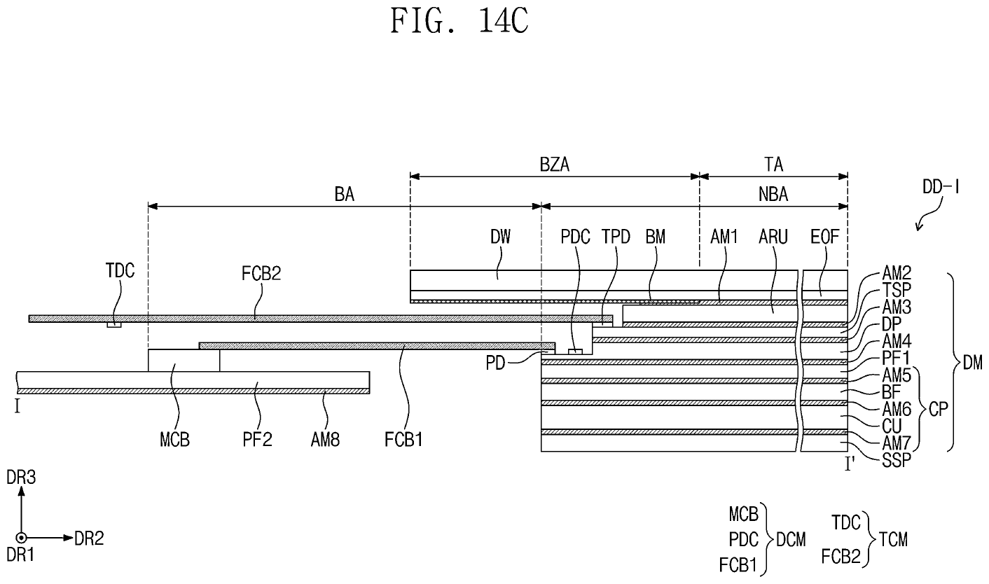

FIGS. 14A to 14C are cross-sectional views of a method of manufacturing a display device according to an embodiment of the disclosure. In FIGS. 14A to 14C, the same reference numerals denote the same elements in the above-described embodiments, and thus, any repetitive detailed description of the same elements as those described above will be omitted.

Referring to FIGS. 14A and 14B, in an embodiment of a method of manufacturing a display device, the light blocking pattern BM corresponding to the bezel area BZA may be printed on the transparent film EOF to form the upper structure UM. The upper structure UM may be inverted upside down and may be coupled with the display module (or the lower module) DM. The light blocking pattern BM may be directly disposed on the lower surface of the transparent film EOF. The light blocking pattern BM may cover the bent portion of the first and second circuit boards FCB1 and FCB2 (refer to FIG. 13D) when viewed in the plan view.

FIGS. 14A and 14B show an embodiment having the structure in which the light blocking pattern BM is disposed between the optical unit ARU and the transparent film EOF as a representative example, however, according to an embodiment, the position of the light blocking pattern BM may be changed. In an embodiment, for example, the upper structure UM may be coupled with the display module DM without being inverted upside down, and thus, the light blocking pattern BM may be disposed on the upper surface of the transparent film EOF. In this case, the light blocking pattern BM may be disposed between the transparent film EOF and the coating window DW like the light blocking pattern BM of FIG. 8.

Referring to FIG. 14C, the coating window DW may be formed on the upper surface of the transparent film EOF. The coating window DW may be formed by coating the resin material on the transparent film EOF and curing the coated resin material.

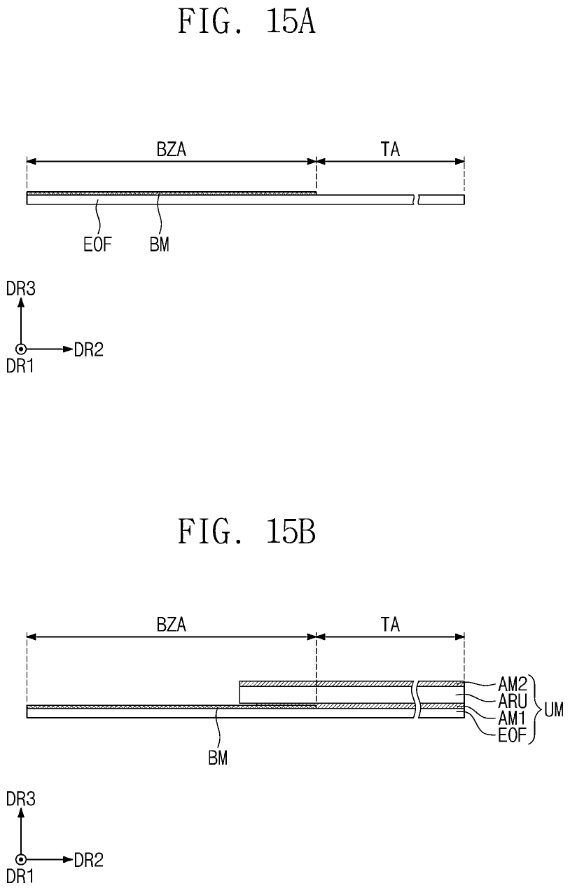

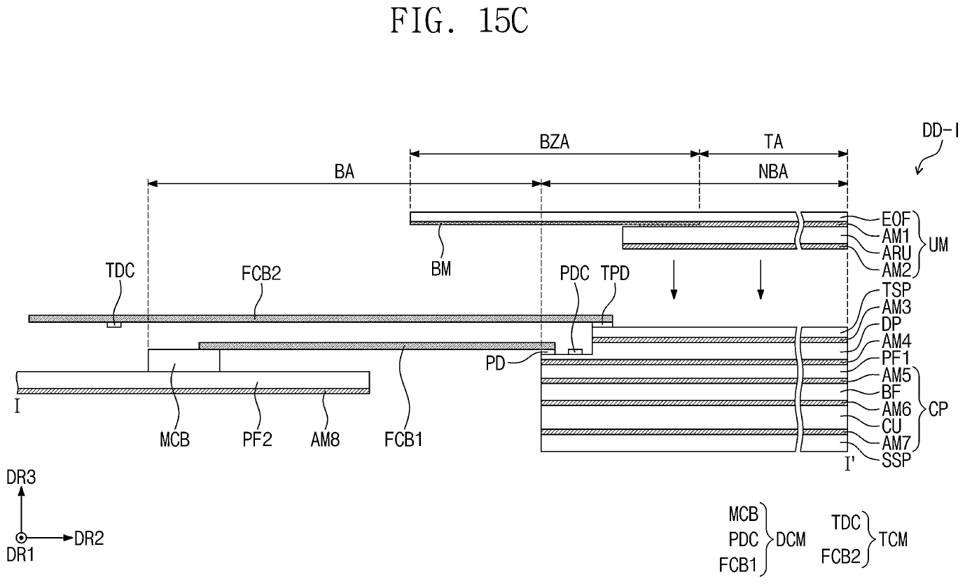

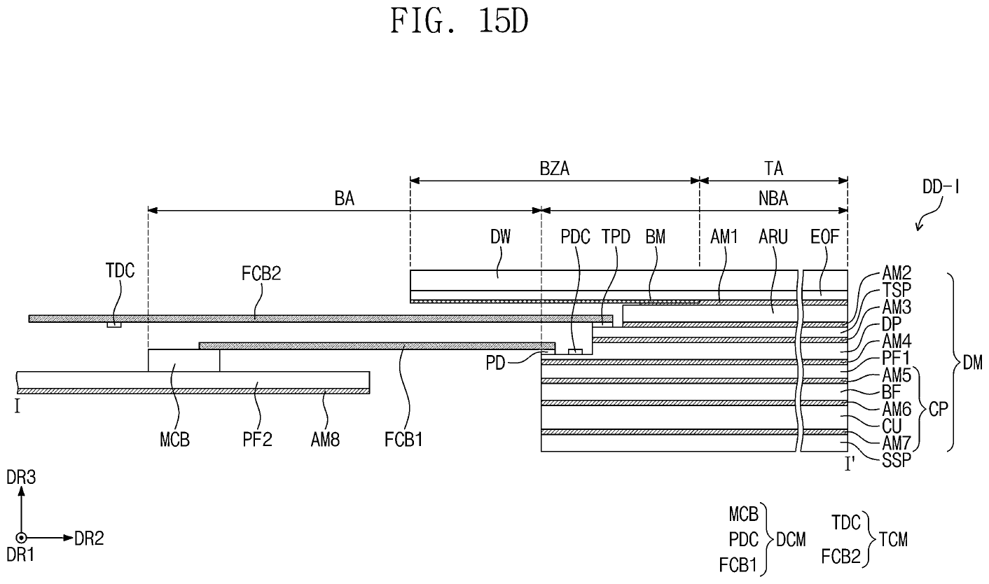

FIGS. 15A to 15D are cross-sectional views of a method of manufacturing a display device according to an embodiment of the disclosure. In FIGS. 15A to 15D, the same reference numerals denote the same elements in the above-described embodiments, and thus, any repetitive detailed description of the same elements as those described above will be omitted.

Referring to FIGS. 15A and 15B, in an embodiment of a method of manufacturing a display device, the light blocking pattern BM may be directly formed on the lower surface of the transparent film EOF. Then, the optical unit ARU overlapping the display area DP-DA (refer to FIG. 3) may be formed on the lower surface of the transparent film EOF and on the light blocking pattern BM. The second adhesive layer AM2 may be attached to one surface of the optical unit ARU. The upper structure UM that includes the transparent film EOF, the first and second adhesive layers AM1 and AM2, and the optical unit ARU may be formed through the above-described processes.

Referring to FIG. 15C, the upper structure UM may be coupled with the lower module after being inverted upside down. In an embodiment, the lower module may include the display panel DP, the touch sensing panel TSP, the first and second protective layers PF1 and PF2, the protective panel CP, and the support panel SSP. The light blocking pattern BM may cover the bent portions of the first and second circuit boards FCB1 and FCB2 (refer to FIG. 13D) when viewed in the plan view. The upper structure UM may be coupled with the lower module, and the preliminary display device DD-I may be formed.

Referring to FIG. 15D, the coating window DW may be formed on the upper surface of the transparent film EOF. The coating window DW may be formed by coating the resin material on the transparent film EOF and curing the coated resin material.

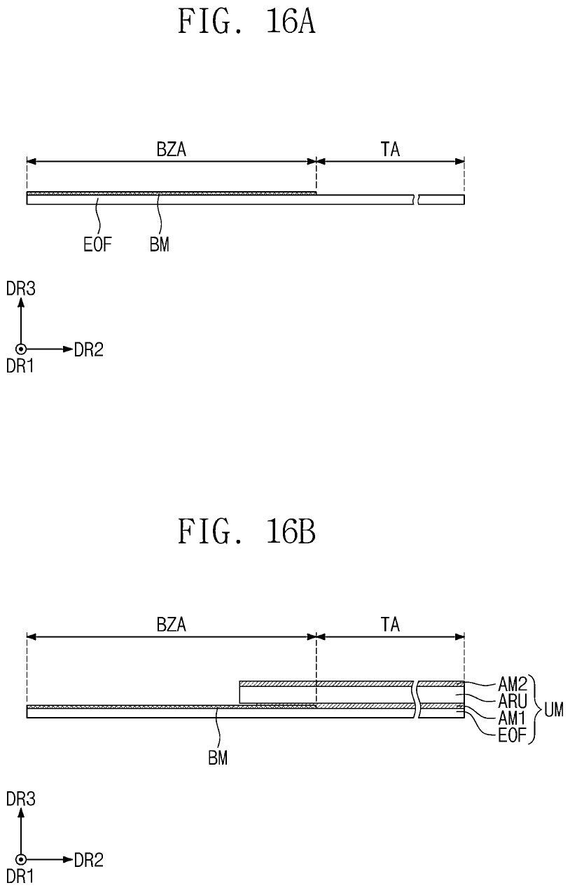

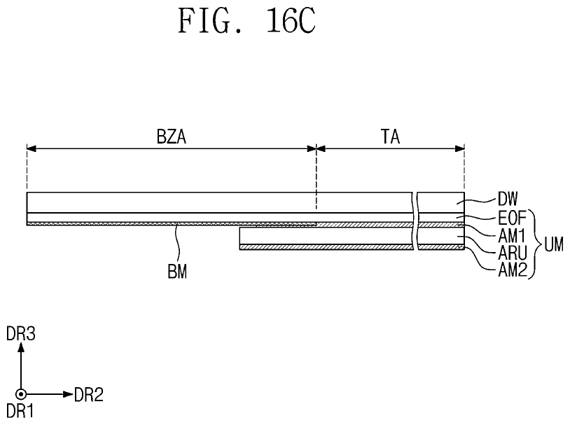

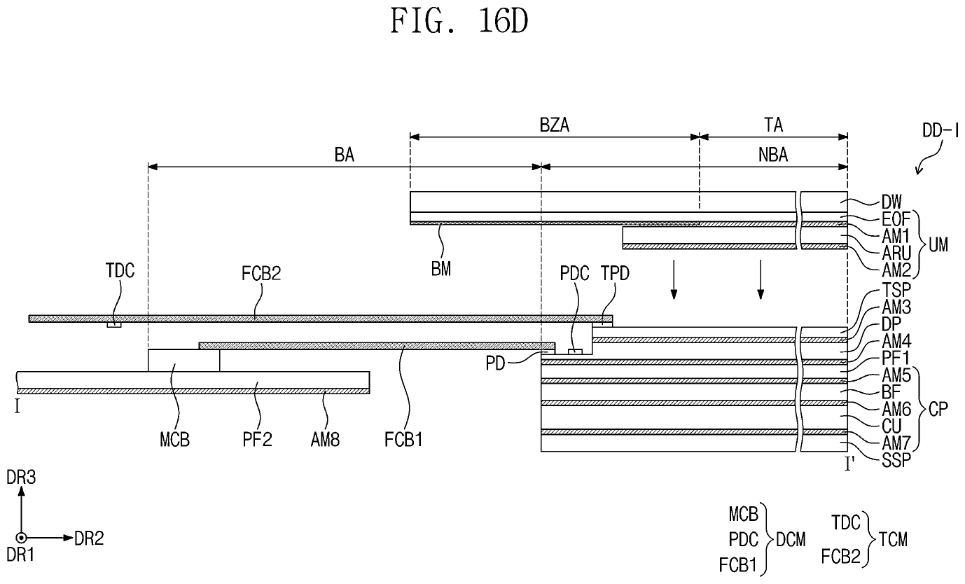

FIGS. 16A to 16D are cross-sectional views of a method of manufacturing a display device according to an embodiment of the disclosure. In FIGS. 16A to 16D, the same reference numerals denote the same elements in the above-described embodiments, and thus, any repetitive detailed description of the same elements as those described above will be omitted.

Referring to FIGS. 16A to 16C, in an embodiment of a method of manufacturing a display device, the light blocking pattern BM may be directly formed on the lower surface of the transparent film EOF after being printed on the lower surface of the transparent film EOF. Then, the optical unit ARU overlapping the display area DP-DA (refer to FIG. 3) may be formed on the lower surface of the transparent film EOF and on the light blocking pattern BM. The second adhesive layer AM2 may be attached to one surface of the optical unit ARU. Then, the upper structure UM may be inverted upside down, and the coating window DW may be formed on the transparent film EOF. The coating window DW may be formed by coating the resin material on the transparent film EOF and curing the coated resin material.

Referring to FIG. 16D, the upper structure UM and the coating window DW, which are formed through processes shown in FIGS. 16A to 16C, may be coupled with a lower member. In an embodiment, the lower module may include the display panel DP, the touch sensing panel TSP, the first and second protective layers PF1 and PF2, the protective panel CP, and the support panel SSP. The light blocking pattern BM may cover the bent portion (refer to FIG. 13D) of the first and second circuit boards FCB1 and FCB2 when viewed in the plan view. The upper structure UM may be coupled with the lower module, and thus, the preliminary display device DD-I may be formed.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display device comprising:
a display panel comprising a display area and a non-display area surrounding the display area;
a flexible board overlapping the non-display area and bent to allow a first end thereof to be disposed on a front surface of the display panel and a second end thereof to be disposed on a rear surface of the display panel;
an optical unit disposed on the display panel and overlapping the display area;
a transparent film disposed on the optical unit and covering the display area, the non-display area, and a bent portion of the flexible board when viewed in a plan view; and
a coating window disposed directly on the transparent film and comprising a cured resin material.

2. The display device of claim 1, wherein an outer side surface of the transparent film protrudes further in a direction away from the display area than a point of the bent portion, which is the most distant from the display area, of the flexible board when viewed in the plan view.

3. The display device of claim 1, further comprising:
a light blocking pattern disposed directly on a lower surface of the transparent film and covering the bent portion of the flexible board when viewed in the plan view.

4. The display device of claim 3, further comprising:
an adhesive layer disposed between the transparent film and the optical unit and attaching the transparent film to the optical unit,
wherein the adhesive layer has a thickness greater than a thickness of the light blocking pattern.

5. The display device of claim 1, further comprising:
a light blocking pattern disposed directly on an upper surface of the transparent film and covering the bent portion of the flexible board when viewed in the plan view.

6. The display device of claim 1, wherein an outer side surface of the transparent film is aligned with an outer side surface of the coating window when viewed in a cross-section.

7. The display device of claim 1, wherein the transparent film has a size equal to or greater than a size of the coating window when viewed in the plan view.

8. The display device of claim 1, wherein an upper surface of the coating window comprises:
a first portion which is flat; and
a second portion disposed outside of the first portion and having a thickness decreasing as a distance from a side surface thereof decreases.

9. The display device of claim 1, wherein the transparent film has a thickness equal to or greater than about 20 micrometers and equal to or smaller than about 200 micrometers.

10. The display device of claim 1, wherein an outer side surface of the transparent film protrudes further in a direction away from the display area than an outer side surface of the display panel when viewed in a cross-section.

11. A display device comprising:
a display panel comprising a non-bending area and a bending area extending from an end of the non-bending area and bent;
an optical unit disposed on the display panel and overlapping the non-bending area;
a transparent film disposed on the optical unit and overlapping the bending area and the non-bending area, and covering the bending area when viewed in a plan view; and
a coating window disposed directly on the transparent film and comprising a cured resin material.

12. The display device of claim 11, further comprising:
a bending protective layer disposed on the display panel and bent together with the bending area, wherein the transparent film covers a bent portion of the bending protective layer.

13. The display device of claim 11, wherein an outer side surface of the transparent film protrudes further in a direction away from the non-bending area than a point of the bending area, which is the most distant from the non-bending area, when viewed in the plan view.

14. The display device of claim 12, wherein an outer side surface of the transparent film protrudes further in a direction away from the non-bending area than a point of the bent portion of the bending protective layer, which is the most distant from the non-bending area, when viewed in the plan view.

15. The display device of claim 11, further comprising:
a light blocking pattern disposed directly on a lower surface or an upper surface of the transparent film and covering the bending area when viewed in the plan view.

16. The display device of claim 11, wherein the transparent film has a size equal to or greater than a size of the coating window when viewed in the plan view.

17. A method of manufacturing a display device, the method comprising:
forming an upper structure comprising a transparent film;
coupling the upper structure with a lower module comprising: a display panel comprising a display area and a non-display area surrounding the display area; and a bending member disposed on the display panel and bendable;
forming a coating window directly on the transparent film using a curable resin material; and
bending the bending member, wherein the transparent film covers the display area, the non-display area, and a bent portion of the bending member when viewed in a plan view.

18. The method of claim 17, wherein the forming the upper structure comprises forming a light blocking pattern on an upper surface or a lower surface of the transparent film in a way such that the light blocking pattern covers the bent portion of the bending member when viewed in the plan view after the coupling the upper structure with the lower module.

19. The method of claim 17, wherein the forming the upper structure comprises:
forming a light blocking pattern on an upper surface or a lower surface of the transparent film in a way such that the light blocking pattern covers the bent portion of the bending member when viewed in the plan view after the coupling the upper structure with the lower module; and
forming an optical unit on the transparent film in a way such that the optical unit overlaps the display area after the coupling the upper structure with the lower module.

20. The method of claim 17, wherein the forming the upper structure comprises:
forming a light blocking pattern on an upper surface or a lower surface of the transparent film in a way such that the light blocking pattern covers the bent portion of the bending member when viewed in the plan view after the coupling the upper structure with the lower module; and
forming an optical unit on the transparent film to overlap the display area, wherein the forming the coating window is performed before the coupling the upper structure with the lower module.

21. The method of claim 17, wherein the forming the coating window comprises:
coating the curable resin material on the transparent film; and
curing the curable resin material coated on the transparent film.

22. The method of claim 17, wherein the bending member is a flexible board which overlaps the non-display area and is bent to allow a first end thereof to be disposed on a front surface of the display panel and a second end thereof to be disposed on a rear surface of the display panel.
